(19) United States
(12) Patent Application Publication
(10) Pub. No.: US 2026/0344153 A1
(43) Pub. Date: Oct. 29, 2026

(54) DISPLAY PANEL AND ELECTRONIC DEVICE INCLUDING THE SAME

(71) Applicant: Samsung Display Co., Ltd., Yongin-si (KR)

(72) Inventor: Mankyu JO, Yongin-si (KR)

(73) Assignee: Samsung Display Co., Ltd., Yongin-si (KR)

(21) Appl. No.: 19/659,287

(22) Filed: Apr. 27, 2026

(30) Foreign Application Priority Data
Apr. 29, 2025 (KR) 10-2025-0056742

(51) Int. Cl. H10H 29/49

(52) U.S. Cl. CPC H10H 29/49

(57) ABSTRACT

A display panel includes a first pixel circuit layer and a second pixel circuit layer spaced apart, a first light-emitting diode electrically connected to a transistor of the first pixel circuit layer, a second light-emitting diode electrically connected to a transistor of the second pixel circuit layer, a first line electrically connected to the transistor of the first pixel circuit layer, a second line electrically connected to the transistor of the second pixel circuit layer, and a connection line electrically connecting the first line and the second line and including nanostructures, wherein the connection line includes a first end portion, a second end portion, and a body between the first end portion and the second end portion, the first line overlaps the first end portion of the connection line, and the second line overlaps the second end portion of the connection line.

### CROSS-REFERENCE TO RELATED APPLICATION

This application is based on and claims priority under 35 U.S.C. § 119 to Korean Patent Application No. 10-2025-0056742, filed on Apr. 29, 2025, in the Korean Intellectual Property Office, the disclosure of which is incorporated by reference herein in its entirety.

### BACKGROUND

### 1. Field

One or more embodiments relate to a display panel, and more particularly, to a display panel and an electronic device including the display panel.

### 2. Description of the Related Art

In general, as display panels that visually display electrical signals have been developed, various display panels with excellent characteristics such as a thin design, light weight, and low power consumption, and electronic devices including such display panels, have been developed. For example, research and development have been actively conducted on display panels of various structures such as flexible display panels, which are foldable, rollable, and stretchable, and electronic devices including such display panels.

### SUMMARY

One or more embodiments include a display panel, for example, a flexible display panel, and an electronic device including the display panel.

Additional aspects will be set forth in a portion of the description which follows and, in part, will be apparent from the description, or may be learned by practice of the embodiments of the disclosure.

According to one or more embodiments, a display panel includes: a base layer including a first surface and a second surface opposite to the first surface; a first pixel circuit layer on the first surface of the base layer and including a transistor and insulating layers; a second pixel circuit layer on the first surface of the base layer, spaced apart from the first pixel circuit layer, and including a transistor and insulating layers; a first light-emitting diode on the first pixel circuit layer and electrically connected to the transistor of the first pixel circuit layer; a second light-emitting diode on the second pixel circuit layer and electrically connected to the transistor of the second pixel circuit layer; a first line electrically connected to the transistor of the first pixel circuit layer; a second line electrically connected to the transistor of the second pixel circuit layer; a connection line electrically connecting the first line and the second line, and including nanostructures, a first end portion overlapping the first line, and a second end portion overlapping the second line; a first conductor on a first overlapping portion between the first line and the first end portion of the connection line; and a second conductor on a second overlapping portion between the second line and the second end portion of the connection line.

The nanostructures may include metal-based nanostructures.

The nanostructures may include first and second nanostructures, the connection line may include a body between the first end portion and the second end portion, wherein each of the first end portion and the second end portion includes first nanostructures, and the body includes second nanostructures electrically connected to the first nanostructures, and an elastomer. A portion of the second nanostructures may overlap and contact a portion of the first nanostructures.

Each of the first nanostructures and the second nanostructures may include at least one of a nanowire, a nanofiber, a nanotube, a nanorod, a nanobelt, and a nanoflake.

The first conductor may directly contact the first nanostructures of the first end portion of the connection line, may directly contact a portion of the first line, and at least partially fill a cavity between the first nanostructures in a network structure, and the second conductor may directly contact the first nanostructures of the second end portion of the connection line, may directly contact a portion of the second line, and may at least partially fill a cavity between the first nanostructures in a network structure.

Each of the connection line, the first conductor, and the second conductor may be in a concave portion that is recessed from the first surface of the base layer.

The first conductor may contact the first overlapping portion between the first line and the first end portion on an upper surface of at least one of the insulating layers of the first pixel circuit layer, and the second conductor may contact the second overlapping portion between the second line and the second end portion on an upper surface of at least one of the insulating layers of the second pixel circuit layer.

According to one or more embodiments, a display panel includes: a base layer including a first surface and a second surface opposite to the first surface; a first pixel circuit layer on the first surface of the base layer and including a transistor and insulating layers; a second pixel circuit layer on the first surface of the base layer, spaced apart from the first pixel circuit layer, and including a transistor and insulating layers; a first light-emitting diode on the first pixel circuit layer and configured to be electrically connected to the transistor of the first pixel circuit layer; a second light-emitting diode on the second pixel circuit layer and configured to be electrically connected to the transistor of the second pixel circuit layer; a first line configured to be electrically connected to the transistor of the first pixel circuit layer; a second line configured to be electrically connected to the transistor of the second pixel circuit layer; and a connection line configured to be electrically connected to the first line and the second line and including nanostructures, wherein the connection line includes a first end portion, a second end portion opposite to the first end portion, and a body between the first end portion and the second end portion, wherein the first line is on the first end portion of the connection line and directly contacts the first end portion, and the second line is on the second end portion of the connection line and directly contacts the second end portion.

The nanostructures may include first nanostructures, each of the first end portion and the second end portion of the connection line may include the first nanostructures in a network structure, wherein the first line may directly contact the first nanostructures of the first end portion, and may at least partially fill a cavity between the first nanostructures of the first end portion, the second line may directly contact the first nanostructures of the second end portion, and may at least partially fill a cavity between the first nanostructures of the second end portion.

The nanostructures may include second nanostructures. The body of the connection line may include the second nanostructures configured to be electrically connected to the first nanostructures, and an elastomer. A portion of the second nanostructures may overlap and contact a portion of the first nanostructures.

Each of the first nanostructures and the second nanostructures may include at least one of a nanowire, a nanofiber, a nanotube, a nanorod, a nanobelt, and a nanoflake.

The body of the connection line may be on the first surface of the base layer, the first end portion of the connection line may be on at least one of the insulating layers of the first pixel circuit layer, and the second end portion of the connection line may be on at least one of the insulating layers of the second pixel circuit layer.

Each of the body, the first end portion, and the second end portion of the connection line may be on the first surface of the base layer, wherein the first line extends toward the first surface of the base layer so that a portion of the first line contacts the first end portion, and the second line extends toward the first surface of the base layer so that a portion of the second line contacts the second end portion.

According to one or more embodiments, an electronic device includes: a base layer including a first surface and a second surface opposite to the first surface; a first pixel circuit layer on the first surface of the base layer and including a transistor and insulating layers; a second pixel circuit layer on the first surface of the base layer, spaced apart from the first pixel circuit layer, and including a transistor and insulating layers; a first light-emitting diode on the first pixel circuit layer and configured to be electrically connected to the transistor of the first pixel circuit layer; a second light-emitting diode on the second pixel circuit layer and configured to be electrically connected to the transistor of the second pixel circuit layer; a first line configured to be electrically connected to the transistor of the first pixel circuit layer; a second line configured to be electrically connected to the transistor of the second pixel circuit layer; and a connection line configured to be electrically connected to the first line and the second line and including nanostructures, wherein the connection line includes a first end portion, a second end portion opposite to the first end portion, and a body between the first end portion and the second end portion, wherein the first line overlaps the first end portion of the connection line, and the second line overlaps the second end portion of the connection line.

The nanostructures may include first and second nanostructures, each of the first end portion and the second end portion of the connection line may include the first nanostructures, and the body of the connection line may include the second nanostructures configured to be electrically connected to the first nanostructures, and an elastomer, wherein each of the first nanostructures and the second nanostructures includes at least one of a nanowire, a nanofiber, a nanotube, a nanorod, a nanobelt, and a nanoflake.

The body of the connection line may be on the first surface of the base layer, the first end portion of the connection line may be on at least one of the insulating layers of the first pixel circuit layer, and the second end portion of the connection line may be on at least one of the insulating layers of the second pixel circuit layer.

Each of the body, the first end portion, and the second end portion of the connection line may be on the first surface of the base layer, wherein the first line extends toward the first surface of the base layer so that a portion of the first line contacts the first end portion, and the second line extends toward the first surface of the base layer so that a portion of the second line contacts the second end portion.

The electronic device may further include: a first conductor on a first overlapping portion between the first line and the first end portion; and a second conductor on a second overlapping portion between the second line and the second end portion.

Each of the connection line, the first conductor, and the second conductor may be in a concave portion that is recessed with respect to the first surface of the base layer.

The first conductor may contact the first overlapping portion between the first line and the first end portion on an upper surface of at least one of the insulating layers of the first pixel circuit layer, and the second conductor may contact the second overlapping portion between the second line and the second end portion on an upper surface of at least one of the insulating layers of the second pixel circuit layer.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a perspective view of a display panel according to an embodiment of the disclosure;

FIGS. 2A and 2B are perspective views illustrating a state in which the display panel of FIG. 1 is stretched in a first direction;

FIG. 2C is a perspective view illustrating a state in which the display panel of FIG. 1 is stretched in a second direction;

FIG. 2D is a perspective view illustrating a state in which the display panel of FIG. 1 is stretched in the first direction and the second direction;

FIG. 2E is a perspective view illustrating a state in which the display panel of FIG. 1 is stretched in a third direction;

FIG. 3 is a plan view schematically illustrating a display area of a display panel, according to an embodiment of the disclosure;

FIG. 4 is a cross-sectional view illustrating a first area of FIG. 3;

FIGS. 5A, 5B, and 5C are equivalent circuit diagrams illustrating a pixel of a display panel, according to an embodiment of the disclosure;

FIGS. 6A, 6B, 6C, 6D, and 6E are cross-sectional views schematically illustrating a light-emitting diode of a display panel, according to an embodiment of the disclosure;

FIG. 7 is a plan view schematically illustrating a portion of a display area of a display panel, according to an embodiment of the disclosure;

FIG. 8 is a plan view schematically illustrating a portion of a display panel, according to an embodiment of the disclosure;

FIG. 9 is a cross-sectional view taken along line VIII-VIII′ of FIG. 8;

FIG. 10 is an enlarged cross-sectional view illustrating a portion X of FIG. 9;

FIGS. 11A, 11B, 11C, and 11D are schematic cross-sectional views illustrating a process of manufacturing a display panel, according to an embodiment of the disclosure;

FIGS. 12A, 12B, 12C, and 12D are schematic cross-sectional views illustrating a process of forming a connection line, a first conductor, and a second conductor of FIG. 11C;

FIG. 13 is a cross-sectional view schematically illustrating a display panel, according to an embodiment of the disclosure, which corresponds to a cross-section taken along line VIII-VIII′ of FIG. 8;

FIG. 14 is an enlarged cross-sectional view illustrating a portion XIV of FIG. 13;

FIGS. 15A, 15B, and 15C are cross-sectional views schematically illustrating a process of manufacturing a first line, a second line, a connection line, a first conductor, and a second conductor described with reference to FIG. 14;

FIG. 16 is a cross-sectional view schematically illustrating a display panel, according to an embodiment of the disclosure, which corresponds to a cross-section taken along line VIII-VIII′ of FIG. 8;

FIG. 17 is an enlarged cross-sectional view illustrating a portion XVII of FIG. 16;

FIGS. 18A, 18B, and 18C are cross-sectional views schematically illustrating a process of manufacturing a first line, a second line, and a connection line described with reference to FIG. 17;

FIG. 19 is a cross-sectional view schematically illustrating a display panel, according to an embodiment of the disclosure, which corresponds to a cross-section taken along line VIII-VIII′ of FIG. 8;

FIG. 20 is an enlarged cross-sectional view illustrating a portion XX of FIG. 19;

FIGS. 21A, 21B, and 21C are cross-sectional views schematically illustrating a process of manufacturing a first line, a second line, and a connection line described with reference to FIG. 20;

FIG. 22 is a plan view schematically illustrating a display panel, according to an embodiment of the disclosure;

FIG. 23 is a cross-sectional view taken along line XXIII-XXIII′ of FIG. 22;

FIG. 24 is a perspective view schematically illustrating an embodiment of an electronic device including a display panel, according to an embodiment of the disclosure;

FIG. 25 is a block diagram illustrating an electronic device including a display panel, according to an embodiment of the disclosure; and

FIGS. 26 and 27 are perspective views illustrating an electronic device, according to an embodiment of the disclosure.

### DETAILED DESCRIPTION

Reference will now be made in detail to embodiments, examples of which are illustrated in the accompanying drawings, wherein like reference numerals refer to like elements throughout. The embodiments may have different forms and should not be construed as being limited to the descriptions set forth herein. Accordingly, the embodiments are merely described below, by referring to the figures, to explain aspects of the description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

Hereinafter, embodiments of the disclosure will be described in detail with reference to the accompanying drawings, wherein the same or corresponding elements are denoted by the same reference numerals throughout and a redundant description thereof is omitted.

Although the terms “first,” “second,” etc. may be used to describe various elements, these elements should not be limited by these terms, and these terms are only used to distinguish one element from another.

As used herein, the singular forms “a,” “an,” and “the” are intended to include the plural forms as well, unless the context clearly indicates otherwise.

It will be understood that the terms “including” and “having” are intended to indicate the existence of the features or elements described in the specification, and are not intended to preclude the possibility that one or more other features or elements may exist or may be added.

It will be further understood that, when a layer, region, or component is referred to as being “on” another layer, region, or component, it may be directly on the other layer, region, or component, or may be indirectly on the other layer, region, or component with intervening layers, regions, or components therebetween.

Sizes of components in the drawings may be exaggerated or reduced for convenience of explanation. For example, because sizes and thicknesses of components in the drawings are arbitrarily illustrated for convenience of explanation, the disclosure is not limited thereto.

When a certain embodiment may be implemented differently, a specific process order may be different from the described order. For example, two consecutively described processes may be performed substantially at the same time or may be performed in an order opposite to the described order.

It will be understood that when a layer, region, or component is referred to as being “connected,” the layer, the region, or the component may be directly connected or may be indirectly connected with intervening layers, regions, or components therebetween. For example, when layers, regions, or components are referred to as being “electrically connected,” the layers, the regions, or the components may be directly electrically connected, or may be indirectly electrically connected with intervening layers, regions, or components therebetween.

“At least one of a, b, and c” or “at least one selected from a, b, and c” may indicate only a, only b, only c, both a and b, both a and c, both b and c, all of a, b, and c, or variations thereof.

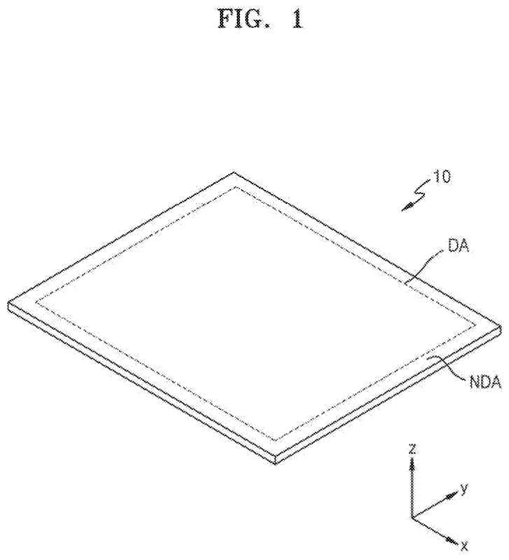

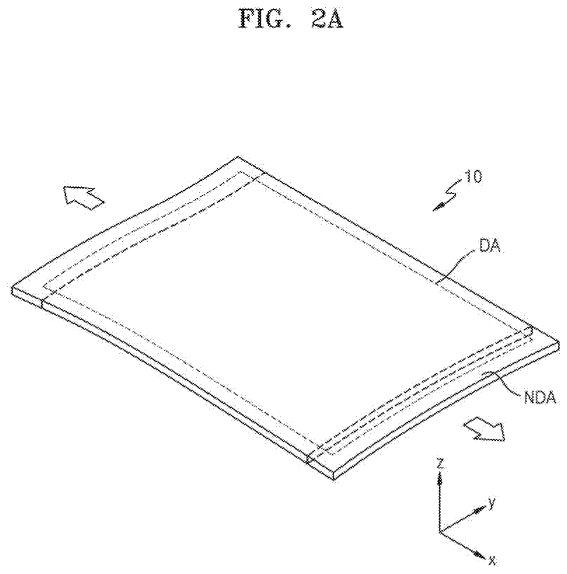

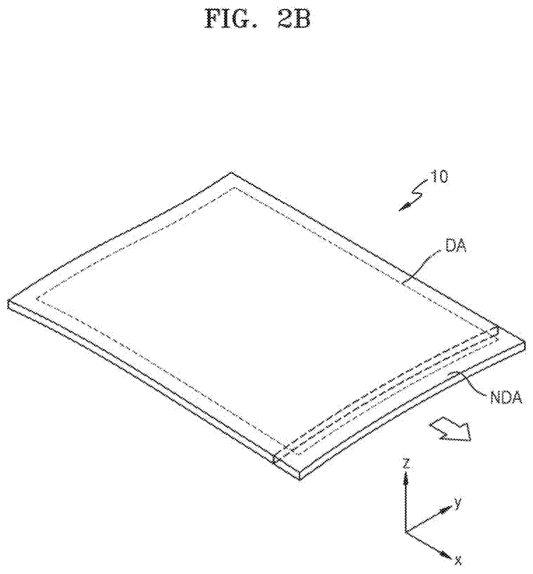

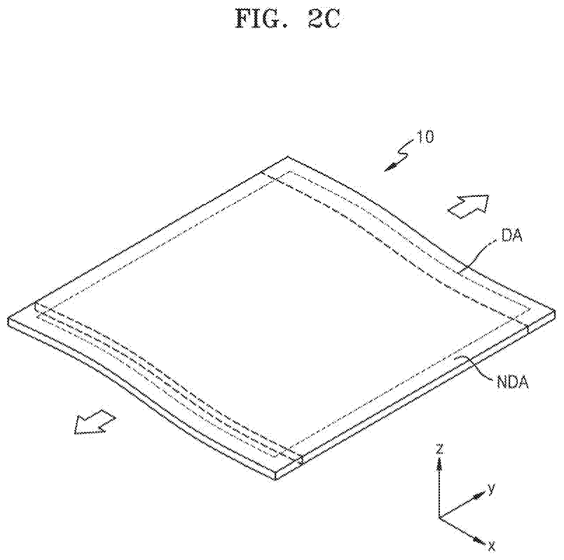

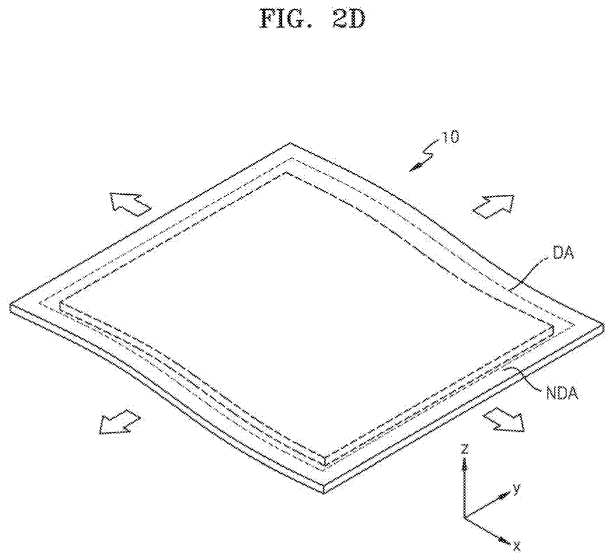

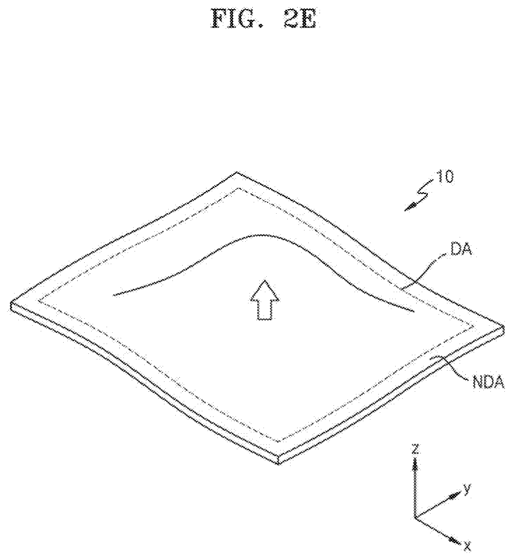

FIG. 1 is a perspective view of a display panel 10, according to an embodiment of the disclosure. FIGS. 2A and 2B are perspective views illustrating a state in which the display panel 10 of FIG. 1 is stretched in a first direction. FIG. 2C is a perspective view illustrating a state in which the display panel 10 of FIG. 1 is stretched in a second direction. FIG. 2D is a perspective view illustrating a state in which the display panel 10 of FIG. 1 is stretched in the first direction and the second direction. FIG. 2E is a perspective view illustrating a state in which the display panel 10 of FIG. 1 is stretched in a third direction.

Referring to FIG. 1, the display panel 10 may include a display area DA and a non-display area NDA. The display area DA may include a plurality of pixels. The display panel 10 may provide a certain image using light emitted from the plurality of pixels. The non-display area NDA may be disposed outside the display area DA. The non-display area NDA may surround (e.g., entirely surround) the display area DA.

The display panel 10 may be stretched or contracted in various directions. The display panel 10 may be stretched in the first direction (e.g., a positive x-axis direction and/or a negative x-axis direction) by an external force applied by a user or an external object. In an embodiment, as shown in FIGS. 2A and 2B, the display area DA and/or the non-display area NDA of the display panel 10 may be stretched in the first direction (e.g., the positive x-axis direction and/or the negative x-axis direction). For example, the display area DA and/or the non-display area NDA of the display panel 10 may be stretched along the positive x-axis direction and the negative x-axis direction as shown in FIG. 2A, or may be stretched along the positive x-axis direction with one side fixed as shown in FIG. 2B.

The display panel 10 may be stretched in the second direction (e.g., a positive y-axis direction and/or a negative y-axis direction) by an external force applied by a user or an external object. In an embodiment, the display area DA and/or the non-display area NDA of the display panel 10 may be stretched in the positive y-axis direction and the negative y-axis direction as shown in FIG. 2C. In other embodiments, the display area DA and/or the non-display area NDA of the display panel 10 may be stretched in the positive y-axis direction or the negative y-axis direction with one side fixed.

The display panel 10 may be stretched in a plurality of directions. For example, the display panel 10 may be stretched in the first direction (e.g., the positive x-axis direction and/or the negative x-axis direction) and the second direction (e.g., the positive y-axis direction and/or the negative y-axis direction) by an external force applied by a user or an external object. The display area DA and/or the non-display area NDA of the display panel 10 may be stretched in the positive x-axis direction, the negative x-axis direction, the positive y-axis direction, and the negative y-axis direction as shown in FIG. 2D.

The display panel 10 may be stretched in the third direction (e.g., a positive z-axis direction or a negative z-axis direction) by an external force applied by a user's body part or an external object. In an embodiment, FIG. 2E illustrates that a portion of the display panel 10, for example, a portion of the display area DA, protrudes in the positive z-axis direction. In other embodiments, a portion of the display panel 10, for example, a portion of the display area DA, may protrude along the positive z-axis direction or may be recessed along the negative z-axis direction.

Although the display panel 10 is stretched in the first direction, the second direction, and/or the third direction in FIGS. 2A, 2B, 2C, 2D, and 2E, the disclosure is not limited thereto. In other embodiments, the display panel 10 may be deformed, for example, bent or twisted, into various irregular shapes along two or more axes.

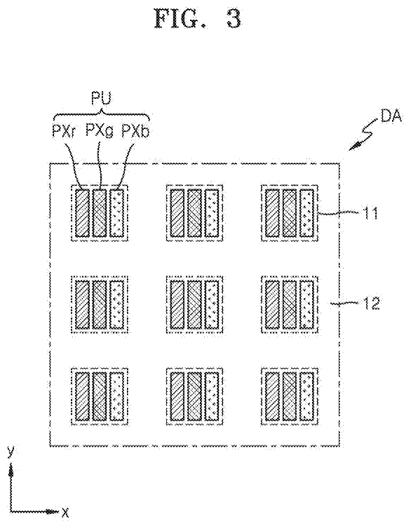

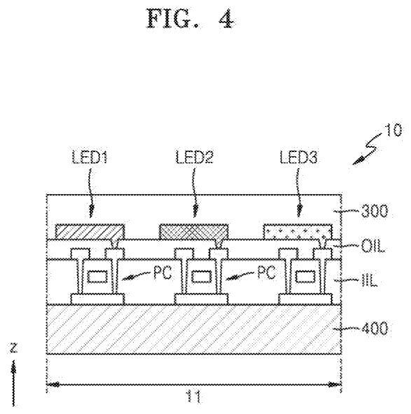

FIG. 3 is a plan view schematically illustrating the display area DA of the display panel 10, according to an embodiment of the disclosure, and FIG. 4 is a cross-sectional view illustrating a first area of FIG. 3.

Referring to FIG. 3, the display area DA may include first areas 11, and a second area 12 surrounding each of the first areas 11. The first areas 11 may be repeatedly arranged along the first direction (e.g., the positive x-axis direction) and the second direction (e.g., a positive y-axis direction) in a plan view.

The display area DA may include the first areas 11 and the second area 12 having different elongations. For example, the display panel 10 may include the first areas 11 having a relatively small elongation and the second area 12 having a relatively large elongation. The term “elongation” used herein refers to a value indicating a change in length (ΔL/L) by which the display panel 10 is stretched without physical damage when an external force is applied to the display panel 10. Here, ΔL denotes a change in length of the display panel 10, and L denotes an initial length of the display panel 10. Accordingly, elongations of the first areas 11 and the second area 12 may refer to changes in length of each first area 11 and the second area 12 when the same external force is applied to each first area 11 and the second area 12.

When the elongation of the first area 11 is less than the elongation of the second area 12, it may mean that deformation of the first area 11 caused by an external force is relatively small. Accordingly, the first area 11 may be referred to as low-deformation area, and the second area 12 may be referred to as a high-deformation area.

The first areas 11 may be spaced apart from each other and may be two-dimensionally arranged in the display area DA. Each of the first area 11 may be an area in which pixels are disposed, and thus, the first area 11 may be referred to as pixel unit area or emission unit area. One or more pixels may be disposed in each first area 11. A pixel unit PU including a set of pixels may be provided in each first area 11, and each pixel unit PU may include a red pixel PXr, a green pixel PXg, and a blue pixel PXb.

The red pixel PXr, the green pixel PXg, and the blue pixel PXb may include a first light-emitting diode LED1, a second light-emitting diode LED2, and a third light-emitting diode LED3, respectively. Referring to FIG. 4, each first area 11 of the display panel 10 may include pixel circuits PC disposed on a base layer 400, an inorganic insulating stack IIL, an organic insulating layer OIL, the first to third light-emitting diodes LED1, LED2, and LED3 electrically connected to the pixel circuits PC, and a protective layer 300. The elongation of the first area 11 may be less than the elongation of the second area 12 due to a stacked structure of the pixel circuits PC, the inorganic insulating stack IIL, the organic insulating layer OIL, and the first to third light-emitting diodes LED1, LED2, and LED3.

The second area 12 may be positioned between adjacent first areas 11. As shown in FIG. 3, in a plan view, the second area 12 may have a shape surrounding each of the first areas 11. The second area 12 may be an area through which connection lines pass. For example, each connection line may electrically connect the pixel circuits PC (see FIG. 4) disposed in two adjacent first areas 11.

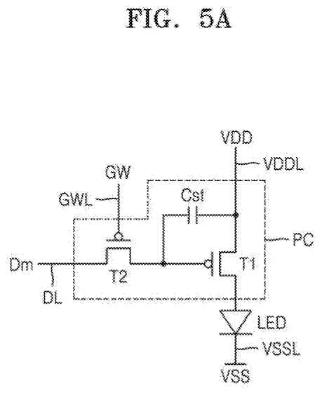

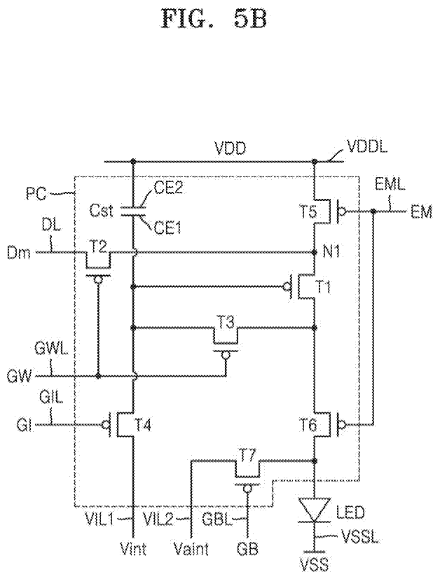

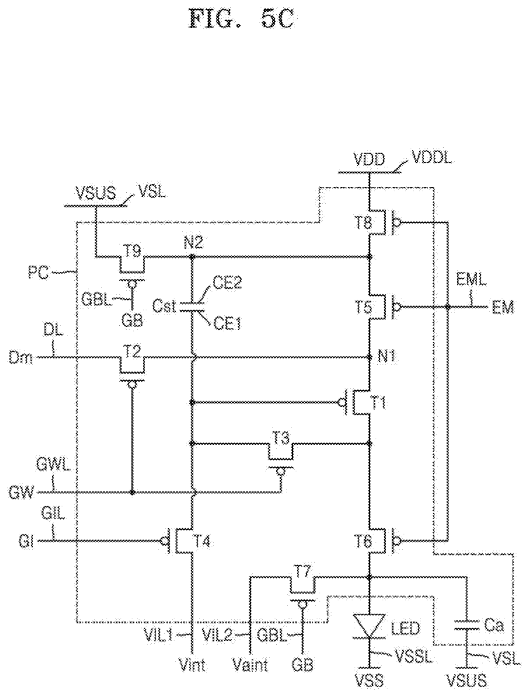

FIGS. 5A, 5B, and 5C are equivalent circuit diagrams illustrating a pixel of a display panel, according to an embodiment of the disclosure.

Referring to FIG. 5A, a light-emitting diode LED corresponding to a pixel may be electrically connected to a pixel circuit PC. The pixel circuit PC may include a first transistor T1, a second transistor T2, and a storage capacitor Cst. The pixel circuit PC may be electrically connected to a signal line and a voltage line. The signal line may include a scan signal line GWL and a data line DL, and the voltage line may include a first voltage line VDDL.

The second transistor T2 may be electrically connected to the scan signal line GWL and the data line DL. The scan signal line GWL may provide a scan signal GW to a gate electrode of the second transistor T2. The second transistor T2 may transmit a data signal Dm input from the data line DL to the first transistor T1 according to the scan signal GW input from the scan signal line GWL.

The storage capacitor Cst may be electrically connected to the second transistor T2 and the first voltage line VDDL, and may store a voltage corresponding to a difference between a voltage received from the second transistor T2 and a first power supply voltage VDD supplied by the first voltage line VDDL.

The first transistor T1 may be a driving transistor and may control driving current flowing through the light-emitting diode LED. The first transistor T1 may be connected to the first voltage line VDDL and the storage capacitor Cst. The first transistor T1 may control the driving current flowing from the first voltage line VDDL to the light-emitting diode LED based on the voltage stored in the storage capacitor Cst. The light-emitting diode LED may emit light having a certain luminance due to the driving current. A first electrode of the light-emitting diode LED may be electrically connected to the first transistor T1, and a second electrode of the light-emitting diode LED may be electrically connected to a second voltage line VSSL that supplies a second power supply voltage VSS.

Although the pixel circuit PC in FIG. 5A includes two transistors and one storage capacitor, in other embodiments, the pixel circuit PC may include three or more transistors.

Referring to FIG. 5B, the pixel circuit PC may include a first transistor T1, a second transistor T2, a third transistor T3, a fourth transistor T4, a fifth transistor T5, a sixth transistor T6, a seventh transistor T7, and a storage capacitor Cst.

The pixel circuit PC may be electrically connected to signal lines and voltage lines. The signal lines may include gate lines (e.g., a scan signal line GWL, a bypass control line GBL, an initialization control line GIL, and an emission control line EML) and a data line DL. The voltage lines may include first and second initialization voltage lines VIL1 and VIL2, and a first voltage line VDDL.

The first voltage line VDDL may transmit a first power supply voltage VDD to the first transistor T1. The first initialization voltage line VIL1 may transmit a first initialization voltage Vint for initializing the first transistor T1 to the pixel circuit PC. The second initialization voltage line VIL2 may transmit a second initialization voltage Vaint for initializing a first electrode of a light-emitting diode LED to the pixel circuit PC.

The first transistor T1 may be electrically connected to the first voltage line VDDL via the fifth transistor T5, which is turned on, and may be electrically connected to the light-emitting diode LED via the sixth transistor T6, which is turned on. The first transistor T1 may function as a driving transistor, and may receive a data signal Dm according to a switching operation of the second transistor T2 and may supply driving current to the light-emitting diode LED.

The second transistor T2 may be a data write transistor and may be electrically connected to the scan signal line GWL and the data line DL. The second transistor T2 may be electrically connected to the first voltage line VDDL via the fifth transistor T5, which is turned on. The second transistor T2 may be turned on according to a scan signal GW received through the scan signal line GWL to perform a switching operation, and may transmit the data signal Dm transmitted through the data line DL to a first node N1.

The third transistor T3 may be electrically connected to the scan signal line GWL, and may be electrically connected to the light-emitting diode LED via the sixth transistor T6, which is turned on. The third transistor T3 may be turned on according to the scan signal GW received through the scan signal line GWL to diode-connect the first transistor T1.

The fourth transistor T4 may be a first initialization transistor and may be electrically connected to the first initialization control line GIL and the first initialization voltage line VIL1. The fourth transistor T4 may be turned on according to an initialization control signal GI received through the initialization control line GIL to initialize a voltage of a gate electrode of the first transistor T1 by transmitting the first initialization voltage Vint from the first initialization voltage line VIL1 to the gate electrode of the first transistor T1. The initialization control signal GI may correspond to a scan signal of another pixel circuit positioned in a previous row with respect to the pixel circuit PC.

The fifth transistor T5 may be an operation control transistor, and the sixth transistor T6 may be an emission control transistor. The fifth transistor T5 and the sixth transistor T6 may be electrically connected to the emission control line EML, and may be simultaneously turned on according to an emission control signal EM received through the emission control line EML to form a current path through which the driving current may flow from the first voltage line VDDL to the light-emitting diode LED. A first electrode of the light-emitting diode LED may be electrically connected to the first transistor T1 through the sixth transistor T6, which is turned on, and a second electrode of the light-emitting diode LED may be electrically connected to a second voltage line VSSL that supplies a second power supply voltage VSS.

The seventh transistor T7 may be a second initialization transistor and may be electrically connected to the bypass control line GBL, the second initialization voltage line VIL2, and the sixth transistor T6. The seventh transistor T7 may be turned on according to a bypass control signal GB received through the bypass control line GBL to initialize the first electrode of the light-emitting diode LED by transmitting the second initialization voltage Vaint from the second initialization voltage line VIL2 to the first electrode of the light-emitting diode LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may maintain a voltage applied to the gate electrode of the first transistor T1 by storing a voltage corresponding to a voltage difference between the first voltage line VDDL and the gate electrode of the first transistor T1.

Referring to FIG. 5C, the pixel circuit PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel circuit PC may be electrically connected to signal lines and voltage lines. The signal lines may include gate lines such as a scan signal line GWL, a bypass control line GBL, an initialization control line GIL, and an emission control line EML, and a data line DL. The voltage lines may include first and second initialization voltage lines VIL1 and VIL2, a sustain voltage line VSL, and a first voltage line VDDL.

The first voltage line VDDL may transmit a first power supply voltage VDD to the first transistor T1. The first initialization voltage line VIL1 may transmit a first initialization voltage Vint for initializing the first transistor T1 to the pixel circuit PC. The second initialization voltage line VIL2 may transmit a second initialization voltage Vaint for initializing a first electrode of a light-emitting diode LED to the pixel circuit PC. The sustain voltage line VSL may provide a sustain voltage VSUS to a second node N2, for example, a second electrode CE2 of the storage capacitor Cst, in/during an initialization period and a data write period.

The first transistor T1 may be electrically connected to the first voltage line VDDL via the fifth transistor T5 and the eighth transistor T8, which are turned on, and may be electrically connected to the light-emitting diode LED via the sixth transistor T6 which is turned on. The first transistor T1 may function as a driving transistor, and may receive a data signal Dm according to a switching operation of the second transistor T2 and may supply driving current to the light-emitting diode LED.

The second transistor T2 may be electrically connected to the scan signal line GWL and the data line DL, and may be electrically connected to the first voltage line VDDL via the fifth transistor T5 and the eighth transistor T8, which are turned on. The second transistor T2 may be turned on according to a scan signal GW received through the scan signal line GWL to perform a switching operation, and may transmit the data signal Dm received through the data line DL to a first node N1.

The third transistor T3 may be electrically connected to the scan signal line GWL, and may be electrically connected to the light-emitting diode LED via the sixth transistor T6, which is turned on. The third transistor T3 may be turned on according to the scan signal GW received through the scan signal line GWL to compensate for a threshold voltage of the first transistor T1 by diode-connecting the first transistor T1.

The fourth transistor T4 may be electrically connected to the initialization control line GIL and the first initialization voltage line VIL1, and may be turned on according to an initialization control signal GI received through the initialization control line GIL to initialize a voltage of a gate electrode of the first transistor T1 by transmitting the first initialization voltage Vint from the initialization voltage line VIL1 to the gate electrode of the first transistor T1. The initialization control signal GI may correspond to a scan signal of another pixel circuit positioned in a previous row with respect to the pixel circuit PC.

The fifth transistor T5, the sixth transistor T6, and the eighth transistor T8 may be electrically connected to the emission control line EML, and may be simultaneously turned on according to an emission control signal EM received through the emission control line EML to form a current path through which the driving current flows from the first voltage line VDDL to the light-emitting diode LED. A first electrode of the light-emitting diode LED may be electrically connected to the first transistor T1 through the sixth transistor T6, which is turned on, and a second electrode of the light-emitting diode LED may be electrically connected to a second voltage line VSSL that supplies a second power supply voltage VSS.

The seventh transistor T7 may be a second initialization transistor, and may be electrically connected to the bypass control line GBL, the second initialization voltage line VIL2, and the sixth transistor T6. The seventh transistor T7 may be turned on according to a bypass control signal GB received through the bypass control line GBL to initialize the first electrode of the light-emitting diode LED by transmitting the second initialization voltage Vaint from the second initialization voltage line VIL2 to the first electrode of the light-emitting diode LED.

The ninth transistor T9 may be electrically connected to the bypass control line GBL, the second electrode CE2 of the storage capacitor Cst, and the sustain voltage line VSL. The ninth transistor T9 may be turned on according to a bypass control signal GB received through the bypass control line GBL, and may transmit a sustain voltage VSUS to the second node N2, for example, the second electrode CE2 of the storage capacitor Cst, in/during the initialization period and the data write period.

The eighth transistor T8 and the ninth transistor T9 may be electrically connected to the second node N2, for example, the second electrode CE2 of the storage capacitor Cst. In some embodiments, the eighth transistor T8 may be turned off and the ninth transistor T9 may be turned on in/during the initialization period and the data write period, and the eighth transistor T8 may be turned on and the ninth transistor T9 may be turned off in/during an emission period.

The storage capacitor Cst may include a first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustain voltage line VSL, and the first electrode of the light-emitting diode LED. The auxiliary capacitor Ca may store and maintain a voltage corresponding to a voltage difference between the first electrode of the light-emitting diode LED and the sustain voltage line VSL while the seventh transistor T7 and the ninth transistor T9 are turned on, thereby preventing an increase in black luminance when the sixth transistor T6 is turned off.

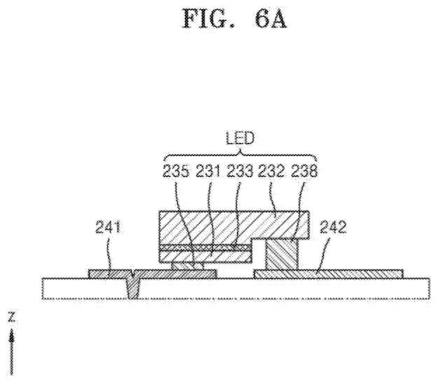

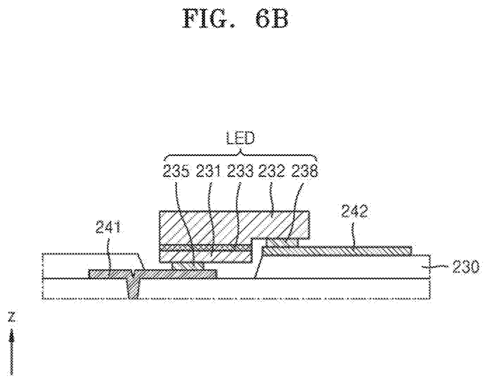

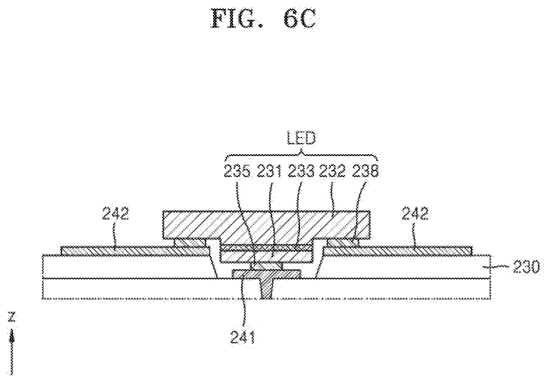

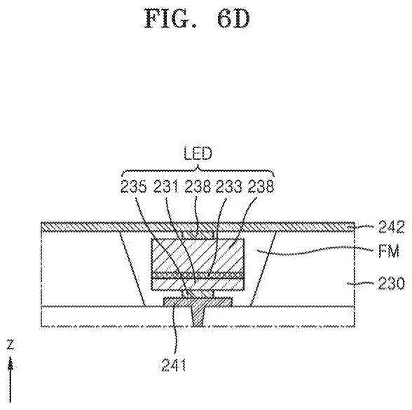

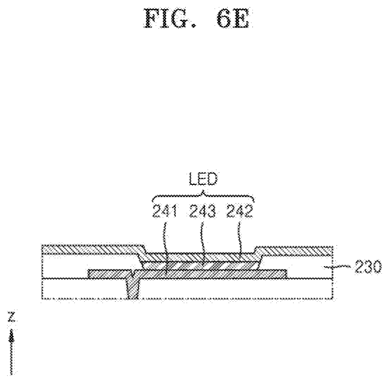

FIGS. 6A, 6B, 6C, 6D, and 6E are cross-sectional views schematically illustrating a light-emitting diode of a display panel, according to an embodiment of the disclosure.

Referring to FIG. 6A, the light-emitting diode LED may include an inorganic light-emitting diode including an inorganic material. The light-emitting diode LED may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the light-emitting diode LED may be electrically connected to a first electrode pad 241 and a second electrode pad 242 positioned on the same layer. The second electrode pad 242 may be a portion of the second voltage line VSSL (see FIG. 5A) or may be a conductive layer electrically connected to the second voltage line VSSL (see FIG. 5A).

In some embodiments, the first semiconductor layer 231 may include a p-type semiconductor layer. The p-type semiconductor layer may be formed of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, and AlInN, and may be doped with a p-type dopant such as Mg, Zn, Ca, Sr, or Ba.

The second semiconductor layer 232 may include, for example, an n-type semiconductor layer. The n-type semiconductor layer may be formed of a semiconductor material having a composition formula of InₓAl_{y}Ga_{1-x-y}N (0≤x≤1, 0≤y≤1, 0≤x+y≤1) selected from among, for example, GaN, AlN, AlGaN, InGaN, InN, InAlGaN, and AlInN, and may be doped with an n-type dopant such as Si, Ge, or Sn.

The intermediate layer 233 may be an active region in which electrons and holes recombine to change to a lower energy level and generate light having a corresponding wavelength. The intermediate layer 233 may include a semiconductor material having a composition formula of InₓAl_{y}Ga_{1-x-y}N (0≤x≤1, 0≤y≤1, 0≤x+y≤1), and may have a single quantum well (SQW) structure or a multi-quantum well (MQW) structure. In other embodiments, the intermediate layer 233 may have a quantum wire structure or a quantum dot structure.

Although the first semiconductor layer 231 includes a p-type semiconductor layer and the second semiconductor layer 232 includes an n-type semiconductor layer in FIG. 6A, the disclosure is not limited thereto. In other embodiments, the first semiconductor layer 231 may include an n-type semiconductor layer, and the second semiconductor layer 232 may include a p-type semiconductor layer.

Although the first electrode pad 241 and the second electrode pad 242 are disposed on the same layer in FIG. 6A, the disclosure is not limited thereto. Referring to FIG. 6B, the first electrode pad 241 and the second electrode pad 242 may be respectively disposed on different layers. A bank layer 230 having an opening overlapping at least a portion of the first electrode pad 241 may be disposed on the first electrode pad 241, and the second electrode pad 242 may be disposed on a top surface (or upper surface) of the bank layer 230. The structure of the light-emitting diode LED of FIG. 6B is the same as that described with reference to FIG. 6A.

In other embodiments, as shown in FIG. 6C, the second electrode pad 242 may be disposed on sides (e.g., opposite sides) of the first electrode pad 241 in a cross-sectional view. The bank layer 230 may have an opening overlapping at least a portion of the first electrode pad 241, and the second electrode pad 242 may be disposed around the opening of the bank layer 230. In some embodiments, in a plan view, the second electrode pad 242 may have a closed loop shape surrounding (e.g., entirely surrounding) the opening of the bank layer 230 and/or the first electrode pad 241. The structure of the light-emitting diode LED of FIG. 6C is the same as that described with reference to FIG. 6A.

Although the first electrode 235 and the second electrode 238 of the light-emitting diode LED face the same direction (e.g., downward, negative z-axis direction) in FIGS. 6A, 6B, and 6C, the disclosure is not limited thereto. As shown in FIG. 6D, the first electrode 235 and the second electrode 238 of the light-emitting diode LED may face opposite directions.

The bank layer 230 may have an opening through which at least a portion of the first electrode pad 241 is exposed, and a thickness of the bank layer 230 may be substantially the same as a thickness of the light-emitting diode LED. The opening of the bank layer 230 may be filled with a filling material FM, and the second electrode pad 242 may be disposed on a top surface (or upper surface) of the bank layer 230 to be electrically connected to (or contact) the second electrode 238 of the light-emitting diode LED. The filling material FM may be an organic material having insulating properties.

Although the light-emitting diode LED includes an inorganic light-emitting diode including an inorganic material in FIGS. 6A, 6B, 6C, and 6D, the disclosure is not limited thereto. Referring to FIG. 6E, the light-emitting diode LED may include an organic light-emitting diode (OLED) including an organic material. For example, the light-emitting diode LED may include a first electrode pad (or the first electrode 241), an organic emission layer 243 overlapping the first electrode pad 241 through an opening of the bank layer 230 disposed on the first electrode pad 241, and a second electrode pad (or the second electrode 242) on the organic emission layer 243. The second electrode pad 242 may be shared by multiple light-emitting diodes LED. For example, the second electrode pad 242 of any one light-emitting diode LED may be integrally connected to the second electrode pad 242 of another light-emitting diode LED.

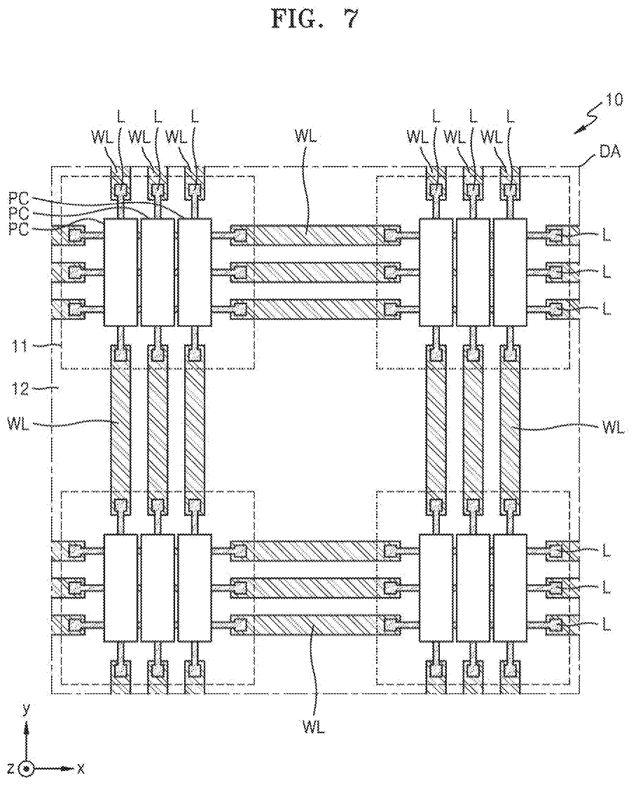

FIG. 7 is a plan view schematically illustrating a portion of the display area DA of the display panel 10, according to an embodiment of the disclosure. FIG. 7 illustrates conductive lines L (hereinafter, referred to as lines) electrically connected to the pixel circuits PC disposed in the display area DA. The pixel circuits PC disposed in each of the first areas 11 of FIG. 7 may be electrically connected to light-emitting diodes corresponding to the pixels PXr, PXg, and PXb described with reference to FIG. 3.

Referring to FIG. 7, the pixel circuit PC for driving the light-emitting diode of each pixel may be disposed in each first area 11. FIG. 7 illustrates that three pixel circuits PC are disposed in each first area 11. Each pixel circuit PC may include a transistor and a capacitor, like the pixel circuits PC described with reference to FIGS. 5A, 5B, and 5C.

Each of the first area 11 may have elongation smaller than that of the second area 12. Accordingly, when the display panel 10 is stretched, the first areas 11 may undergo less deformation than the second area 12. The first areas 11 may be referred to as low-deformation areas (or low-deformation portions) as described above. The first areas 11 may be areas in which light-emitting diodes are disposed, and may be referred to as pixel unit areas or emission unit areas.

The second area 12 may surround the first areas 11, and may have an elongation greater than that of each of the first areas 11. The second area 12 may be an area in which main deformation occurs when the display panel 10 is stretched. Because the second area 12 is disposed between a plurality of first areas 11, the second area 12 may be referred to as a connection portion for connecting the first areas 11. The second area 12 may be referred to as a main deformation area (or a main deformation portion) or a high-deformation area (or a high-deformation portion). The second area 12 may be a portion of the display area in which a light-emitting diode is not disposed and may be referred to as a non-pixel unit area or a non-emission unit area.

The lines L electrically connected to the pixel circuit PC may be disposed in the display area DA. In an embodiment, FIG. 7 illustrates that the lines L extending in the first direction (e.g., the positive x-axis direction or the negative x-axis direction) and the lines L extending in the second direction (e.g., the positive y-axis direction or the negative y-axis direction) are electrically connected to the pixel circuits PC. Each of the lines L may be electrically connected to the pixel circuit PC through a contact hole.

Any one line L disposed in the first area 11 may be electrically connected to any one line L disposed in an adjacent first area 11 through a connection line WL. The lines L may include a voltage line and/or a signal line. The lines L may include a gate line for providing a gate signal to a gate electrode of a transistor, a data line, and/or a voltage line. In an embodiment, the lines L extending in the first direction (e.g., the positive x-axis direction or the negative x-axis direction) may include the gate lines (e.g., the scan signal line GWL, the bypass control line GBL, the initialization control line GIL, and the emission control line EML), and/or the second voltage line VSSL described with reference to FIGS. 5A, 5B, and 5C. The lines L extending in the second direction (e.g., the positive y-axis direction or the negative y-axis direction) may include the data line DL, the first initialization voltage line VIL1, the second initialization voltage line VIL2, the sustain voltage line VSL, and/or the first voltage line VDDL described with reference to FIGS. 5A, 5B, and 5C.

The connection line WL disposed in the second area 12 may be more stretchable than the lines L disposed in each first area 11. An elongation of each connection line WL may be greater than an elongation of each line L.

Each of the lines L may include at least one material selected from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu). In some embodiments, each of the lines L may have a single layer structure or a multi-layer structure including the above metal. In an embodiment, each of the lines L may include a metal thin film having a three-layer structure of titanium (Ti)/aluminum (Al)/titanium (Ti).

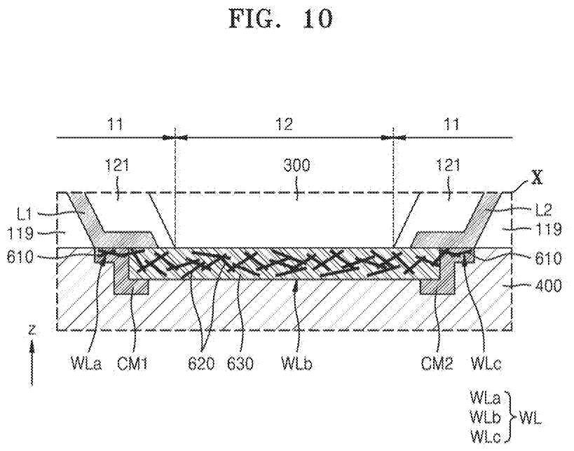

The connection line WL may have an elongation greater than an elongation of each line L. The connection line WL may include nanostructures. For example, a body of the connection line WL may include a composite material including conductive nanostructures and an insulating elastomer, and an end portion of the connection line WL may be connected to the body and may include conductive nanostructures. A specific structure of the connection line WL will be described below with reference to FIGS. 10, 14, 17, and 20.

Although the connection line WL has a linear shape in a plan view in the embodiment described with reference to FIG. 7, the disclosure is not limited thereto. In an embodiment, the connection line WL may have a shape other than a linear shape in a plan view, for example, a serpentine shape in a plan view. In some embodiments, the connection line WL may have a wave shape with two or more inflection points.

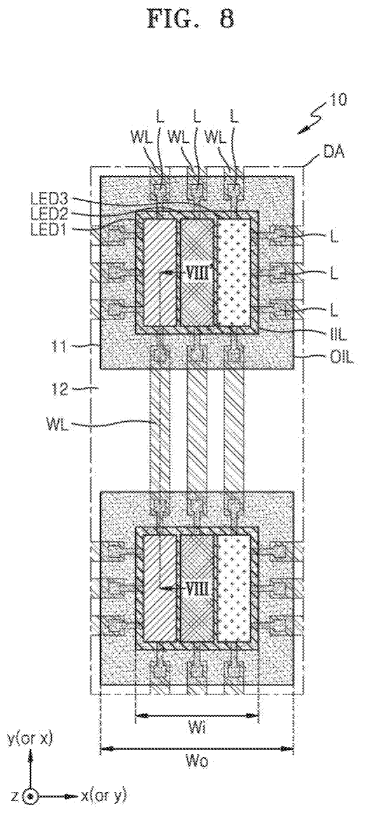

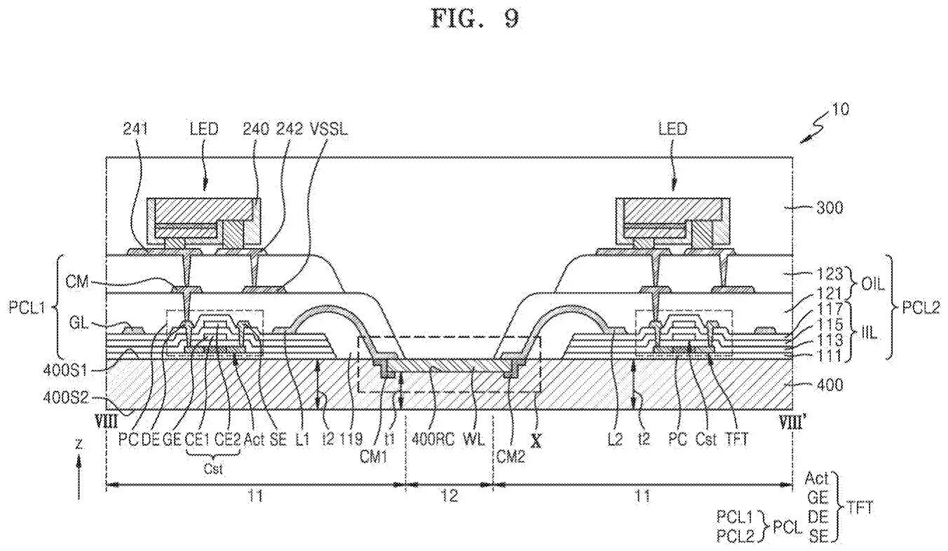

FIG. 8 is a plan view illustrating a portion of a display panel 10, according to an embodiment of the disclosure, and FIG. 9 is a cross-sectional view taken along line VIII-VIII′ of FIG. 8.

Referring to FIG. 8, light-emitting diodes, for example, the first to third light-emitting diodes LED1, LED2, and LED3 (see FIG. 9), disposed in each first area 11 may be electrically connected to the pixel circuits PC (see FIG. 7) described with reference to FIG. 7. The inorganic insulating stack IIL and the organic insulating layer OIL may be disposed in each first area 11. The first to third light-emitting diodes LED1, LED2, and LED3 may be disposed on the inorganic insulating stack IIL and the organic insulating layer OIL.

Referring to FIG. 8, the display panel 10 may include the first areas 11 and the second area 12 between the first areas 11 as described with reference to FIG. 7. As shown in FIG. 9, because components of the display panel 10 are disposed on the base layer 400, when the display panel 10 includes the first areas 11 and the second area 12, it may mean that the base layer 400 includes the first areas 11 and the second area 12.

Referring to FIG. 9, the display panel 10 may include the pixel circuit layer PCL disposed in each of two adjacent first areas 11 and the light-emitting diode LED on the pixel circuit layer PCL. The light-emitting diode LED of FIG. 9 may correspond to any one of the first to third light-emitting diodes LED1, LED2, and LED3 of FIG. 8.

Each pixel circuit layer PCL may include the inorganic insulating stack IIL, the pixel circuit PC, and the organic insulating layer OIL. Hereinafter, for convenience of explanation, one of the pixel circuit layers PCL disposed in two adjacent first areas 11 is referred to as a first pixel circuit layer PCL1 and the other is referred to as a second pixel circuit layer PCL2.

Each of the first pixel circuit layer PCL1 and the second pixel circuit layer PCL2 may be disposed on the base layer 400. Each of the first pixel circuit layer PCL1 and the second pixel circuit layer PCL2 may be disposed on a first surface 400S1 (e.g., a top surface) of the base layer 400.

The base layer 400 may absorb stress generated when the display panel 10 is stretched. The base layer 400 may include an elastomer. The base layer 400 may include at least one of thermoplastic polyurethane, silicone, thermoplastic rubber, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomer, ethylene-vinyl acetate, polydimethylsiloxane (PDMS), styrene-ethylene-butylene-styrene (SEBS), and Ecoflex™ (Ecoflex™ being a registered trademark of Smooth-On, Inc.).

Each of the first pixel circuit layer PCL1 and the second pixel circuit layer PCL2 may include the inorganic insulating stack IIL, the pixel circuit PC, and the organic insulating layer OIL. The inorganic insulating stack IIL may include a buffer layer 111, a gate insulating layer 113, a first interlayer insulating layer 115, and a second interlayer insulating layer 117. The organic insulating layer OIL may include a first organic insulating layer 121 and a second organic insulating layer 123.

Each of the inorganic insulating stack IIL and the organic insulating layer OIL may have an isolated shape as shown in FIG. 8. Each of the inorganic insulating stack IIL and the organic insulating layer OIL may be disposed in each first area 11. The second area 12 in which the inorganic insulating stack IIL and the organic insulating layer OIL are not disposed may be relatively readily deformed.

Each first area 11 may be defined as an area obtained by projecting the inorganic insulating stack IIL and the organic insulating layer OIL along a direction perpendicular to the base layer 400. In an embodiment, when a width Wi of the inorganic insulating stack IIL is less than a width Wo of the organic insulating layer OIL as shown in FIG. 8, the width Wo of the organic insulating layer OIL may correspond to a width of each first area 11.

The first pixel circuit layer PCL1 and the second pixel circuit layer PCL2 may be spaced apart from each other. When the first pixel circuit layer PCL1 and the second pixel circuit layer PCL2 are spaced apart from each other, it may mean that the inorganic insulating stack IIL, the pixel circuit PC, and the organic insulating layer OIL of the first pixel circuit layer PCL1 are spaced apart from the inorganic insulating stack IIL, the pixel circuit PC, and the organic insulating layer OIL of the second pixel circuit layer PCL2, respectively.

The inorganic insulating stack IIL may be disposed in each first area 11, and may not be disposed in the second area 12. The inorganic insulating stacks IIL disposed in the first areas 11 may be spaced apart from each other in a plan view. For example, the buffer layer 111, the gate insulating layer 113, the first interlayer insulating layer 115, and the second interlayer insulating layer 117 of the first pixel circuit layer PCL1 may be separated and spaced apart from the buffer layer 111, the gate insulating layer 113, the first interlayer insulating layer 115, and the second interlayer insulating layer 117 of the second pixel circuit layer PCL2, respectively.

For example, the organic insulating layer OIL may be disposed in each first area 11, and may not be disposed in the second area 12. For example, the first organic insulating layer 121 and the second organic insulating layer 123 of the first pixel circuit layer PCL1 may be separated and spaced apart from the first organic insulating layer 121 and the second organic insulating layer 123 of the second pixel circuit layer PCL2, respectively.

As shown in FIG. 9, the buffer layer 111 may be disposed on the base layer 400, and the pixel circuit PC may be disposed on the buffer layer 111. The buffer layer 111 may include an inorganic insulating material such as silicon oxide, silicon nitride, or silicon oxynitride.

A thin-film transistor TFT of the pixel circuit PC may include a semiconductor layer Act, a gate electrode GE, a source electrode SE, and a drain electrode DE. Although the thin-film transistor TFT is illustrated as a top gate type transistor in which the gate electrode GE is disposed on the semiconductor layer Act with the gate insulating layer 113 therebetween in FIG. 9, according to other embodiments, the thin-film transistor TFT may be a bottom gate type transistor.

The semiconductor layer Act may include polysilicon. In another example, the semiconductor layer Act may include amorphous silicon, an oxide semiconductor, or an organic semiconductor. The gate electrode GE may include a metal thin film formed of a low-resistance metal material. The gate electrode GE may include a conductive material including molybdenum (Mo), aluminum (Al), copper (Cu), or titanium (Ti), and may have a single layer structure or a multi-layer structure including the above material. For example, the gate electrode GE may include a metal thin film having a three-layer structure of titanium (Ti)/aluminum (Al)/titanium (Ti).

The gate insulating layer 113 between the semiconductor layer Act and the gate electrode GE may include an inorganic insulating material such as silicon oxide, silicon nitride, silicon oxynitride, aluminum oxide, or titanium oxide. The gate insulating layer 113 may have a single layer structure or a multi-layer structure including the above material.

The source electrode SE and the drain electrode DE may be positioned on the same layer, for example, the second interlayer insulating layer 117, and may include the same material. The source electrode SE and the drain electrode DE may include a metal thin film formed of a low-resistance metal material. The source electrode SE and the drain electrode DE may be respectively connected to a source region and a drain region of the semiconductor layer Act.

Each of the source electrode SE and the drain electrode DE may include a conductive material including molybdenum (Mo), aluminum (Al), copper (Cu), or titanium (Ti), and may have a single layer structure or a multi-layer structure including the above material. For example, each of the source electrode SE and the drain electrode DE may include a metal thin film having a three-layer structure of titanium (Ti)/aluminum (Al)/titanium (Ti), like the gate electrode GE. The second interlayer insulating layer 117 may include an inorganic insulating material such as silicon oxide, silicon nitride, silicon oxynitride, aluminum oxide, or titanium oxide, and may have a single layer structure or a multi-layer structure including the above material.

The storage capacitor Cst may include the first electrode CE1 and the second electrode CE2 overlapping each other with the first interlayer insulating layer 115 therebetween. The storage capacitor Cst may overlap the thin-film transistor TFT. As illustrated in FIG. 9, the gate electrode GE of the thin-film transistor TFT may function as the first electrode CE1 of the storage capacitor Cst. In other embodiments, the storage capacitor Cst may not overlap the thin-film transistor TFT. The storage capacitor Cst may be covered by the second interlayer insulating layer 117.

The first interlayer insulating layer 115 may be disposed between the gate insulating layer 113 and the second interlayer insulating layer 117. Each of the first interlayer insulating layer 115 and the second interlayer insulating layer 117 may include an inorganic insulating material such as silicon oxide, silicon nitride, silicon oxynitride, aluminum oxide, or titanium oxide, and may have a single layer structure or a multi-layer structure including the above material.

The second electrode CE2 of the storage capacitor Cst may include a conductive material and may have a single layer structure or a multi-layer structure. The second electrode CE2 may include a metal thin film formed of a low-resistance metal material. The second electrode CE2 may include a conductive material including molybdenum (Mo), aluminum (Al), copper (Cu), or titanium (Ti), and may have a single layer structure or a multi-layer structure including the above material. For example, the second electrode CE2 may include a metal thin film having a three-layer structure of titanium (Ti)/aluminum (Al)/titanium (Ti).

The first organic insulating layer 121 may be disposed on the second interlayer insulating layer 117. The second organic insulating layer 123 may be disposed on the first organic insulating layer 121. A connection electrode CM and the second voltage line VSSL may be disposed on the first organic insulating layer 121. The connection electrode CM may electrically connect the pixel circuit PC to the first electrode pad 241. The second voltage line VSSL may be electrically connected to the second electrode pad 242.

Each of the connection electrode CM and the second voltage line VSSL may include a metal thin film formed of a low-resistance metal material. Each of the connection electrode CM and the second voltage line VSSL may include a conductive material including molybdenum (Mo), aluminum (Al), copper (Cu), or titanium (Ti), and may have a single layer structure or a multi-layer structure including the above material. For example, each of the connection electrode CM and the second voltage line VSSL may include a metal thin film having a three-layer structure of titanium (Ti)/aluminum (Al)/titanium (Ti).

The first electrode pad 241 and the second electrode pad 242 may be disposed on the second organic insulating layer 123. The first electrode pad 241 may be electrically connected to the thin-film transistor TFT through the connection electrode CM between the first organic insulating layer 121 and the second organic insulating layer 123.

The light-emitting diode LED on the first electrode pad 241 and the second electrode pad 242 may be the same as the light-emitting diode LED described with reference to FIG. 6A. In other embodiments, the light-emitting diode LED may have a structure as shown in FIGS. 6B, 6C, 6D, and 6E. A surface of the light-emitting diode LED may be covered by a protective material layer 240 including an organic insulating material or including an inorganic insulating material and an organic insulating material.

In an embodiment, the organic insulating layer OIL may further include a third organic insulating layer 119 disposed to cover a side surface of the inorganic insulating stack IIL. The third organic insulating layer 119 may have a closed loop shape in a plan view to cover a side surface of the inorganic insulating stack IIL. For example, in a plan view, the third organic insulating layer 119 may have a frame shape.

The line L described with reference to FIG. 8 may be electrically connected to the pixel circuit PC of the pixel circuit layer PCL. FIG. 9 illustrates that a line (hereinafter, referred to as a first line L1) disposed in any one first area 11 among the lines L of FIG. 8 is electrically connected to the pixel circuit PC of the first pixel circuit layer PCL1, and a line (hereinafter, referred to as a second line L2) disposed in another first area 11 is electrically connected to the pixel circuit PC of the second pixel circuit layer PCL2.

The first line L1 and the second line L2 of FIG. 9 may be signal lines or voltage lines. For example, the first line L1 and the second line L2 may correspond to the gate line, the data line DL, the first voltage line VDDL, the second voltage line VSSL, the first initialization voltage line VIL1, the second initialization voltage line VIL2, the sustain voltage line VSL described with reference to FIGS. 5A, 5B, and 5C.

Each of the first line L1 and the second line L2 may be disposed on the inorganic insulating stack IIL and may extend toward the connection line WL. For example, each of the first line L1 and the second line L2 may extend toward the connection line WL after passing over a top surface (or upper surface) of the third organic insulating layer 119. A portion of each of the first line L1 and the second line L2 may be positioned between the third organic insulating layer 119 and the first organic insulating layer 121.

Each of the first line L1 and the second line L2 may include a conductive material including molybdenum (Mo), aluminum (Al), copper (Cu), or titanium (Ti), and may have a single layer structure or a multi-layer structure including the above material.

The first line L1 and the second line L2 may respectively overlap end portions of the connection line WL. An overlapping portion between the first line L1 and the end portion of the connection line WL and an overlapping portion between the second line L2 and the end portion of the connection line WL may be positioned between the inorganic insulating stack IIL of the first pixel circuit layer PCL1 and the inorganic insulating stack IIL of the second pixel circuit layer PCL2 in a plan view (e.g., in a direction perpendicular to the first surface 400S1 of the base layer 400).

A first conductor CM1 may be disposed on the overlapping portion between the first line L1 and the connection line WL. A second conductor CM2 may be disposed on the overlapping portion between the second line L2 and the connection line WL. Each of the first conductor CM1 and the second conductor CM2 may include a conductive material including molybdenum (Mo), aluminum (Al), copper (Cu), or titanium (Ti), and may have a single layer structure or a multi-layer structure including the above material.

A first end portion of the connection line WL may be disposed between a portion of the first conductor CM1 and a portion of the first line L1. A second end portion of the connection line WL may be disposed between a portion of the second conductor CM2 and a portion of the second line L2.

The first conductor CM1 may improve mechanical coupling and electrical coupling between the first line L1 and the connection line WL, and the second conductor CM2 may improve mechanical coupling and electrical coupling between the second line L2 and the connection line WL. Although the first end portion and the second end portion of the connection line WL including nanostructures respectively overlap the first and second lines L1 and L2, it may be difficult to sufficiently ensure a contact area between the nanostructures of the first and second end portions and the first and second lines L1 and L2. For example, there may be a problem that electrical resistance at connection points between the first line L1 and the connection line WL and at the connection points between the second line L2 and the connection line WL increases, and there may be a problem that a mechanical coupling force decreases. However, in some embodiments, because the first conductor CM1 directly contacts the nanostructures and directly contacts the first line L1 while filling cavities between the nanostructures of the first end portion of the connection line WL, mechanical coupling by an anchoring effect and electrical coupling may be improved. Because the second conductor CM2 directly contacts the nanostructures and directly contacts the second line L2 while filling cavities between the nanostructures of the second end portion of the connection line WL, mechanical coupling by an anchoring effect and electrical coupling through increased contact area may be improved.

The first organic insulating layer 121 corresponding to the first pixel circuit layer PCL1 may extend beyond a side surface of the inorganic insulating stack IIL toward an overlapping structure of the first line L1, the first end portion of the connection line WL, and the first conductor CM1, and may cover the overlapping structure. The first organic insulating layer 121 corresponding to the second pixel circuit layer PCL2 may extend beyond a side surface of the inorganic insulating stack IIL toward the overlapping structure of the second line L2, the second end portion of the connection line WL, and the second conductor CM2, and may cover the overlapping structure.

In an embodiment, each of the connection line WL, the first conductor CM1, and the second conductor CM2 may be formed in the base layer 400. The base layer 400 may include the first surface 400S1 and a second surface 400S2 opposite to the first surface 400S1, and may include a concave portion 400RC that is concave (or recessed) with respect to the first surface 400S1. The connection line WL, the first conductor CM1, and the second conductor CM2 may be disposed in the concave portion 400RC. In an embodiment, the connection line WL may include a bottom surface (or lower surface) facing the concave portion 400RC and a top surface (or upper surface) opposite to the bottom surface (or lower surface), and the top surface (or upper surface) of the connection line WL may be positioned on substantially the same plane as the first surface 400S1 of the base layer 400. When the connection line WL, the first conductor CM1, and the second conductor CM2 have a structure formed in the base layer 400, the base layer 400 may absorb stress which is concentrated on the connection line WL when the display panel 10 is stretched.

A thickness t1 of a first portion of the base layer 400 overlapping the connection line WL may be less than a thickness t2 of a second portion of the base layer 400 overlapping the inorganic insulating stack IIL of the first and second pixel circuit layers PCL1 and PCL2. A thickness of a portion of the base layer 400 overlapping the first and second conductors CM1 and CM2 may also be less than the thickness t2 of the second portion of the base layer 400.

The light-emitting diode LED may be disposed on the pixel circuit layer PCL. For example, the light-emitting diode LED electrically connected to the pixel circuit PC of the first pixel circuit layer PCL1 may be disposed on the first pixel circuit layer PCL1, and the light-emitting diode LED electrically connected to the pixel circuit PC of the second pixel circuit layer PCL2 may be disposed on the second pixel circuit layer PCL2. A surface (e.g., side surface and/or lower surface) of each light-emitting diode LED may be covered by the protective material layer 240. The protective material layer 240 may include an organic insulating material such as polyimide.

The protective layer 300 may be disposed on the light-emitting diode LED and the connection line WL. The protective layer 300 may cover the light-emitting diode LED and the connection line WL.

The protective layer 300 may absorb stress which is transmitted to the light-emitting diode LED and the connection line WL when the display panel 10 is stretched, and may planarize a top surface (or upper surface) of the display panel 10. The protective layer 300 may include an elastomer. For example, the protective layer 300 may include at least one of thermoplastic polyurethane, silicone, thermoplastic rubber, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomer, ethylene-vinyl acetate, polydimethylsiloxane (PDMS), styrene-ethylene-butylene-styrene (SEBS), and Ecoflex™ (Ecoflex™ being a registered trademark of Smooth-On, Inc.).

The protective layer 300 may contact (e.g., directly contact) a portion of the top surface (or upper surface) of the connection line WL, and may contact (e.g., directly contact) a portion of the top surface (or upper surface) of the base layer 400 (e.g., a portion of the top surface of the base layer 400 positioned between the connection lines WL of FIG. 9). In an embodiment, when a material of the protective layer 300 and a material of the base layer 400 are the same, a coupling force between the protective layer 300 and the base layer 400 may be increased, thereby more effectively maintaining the airtightness of the display panel 10.

FIG. 10 is an enlarged cross-sectional view illustrating a portion X of FIG. 9.

Referring to FIG. 10, the connection line WL may include a body WLb, a first end portion WLa disposed on one side of the body WLb, and a second end portion WLc disposed on the other side of the body WLb, and a thickness of the body WLb may be greater than a thickness of each of the first end portion WLa and the second end portion WLc. Along a thickness direction (e.g., the positive z-axis direction or the negative z-axis direction), the first end portion WLa of the connection line WL may be disposed between the first conductor CM1 and a portion of the first line L1, and the second end portion WLc may be disposed between the second conductor CM2 and a portion of the second line L2. The first end portion WLa and the second end portion WLc may be disposed in the first area 11, and the body WLb may extend from any one first area 11 to another first area 11 and may pass through the second area 12.

In an embodiment, as shown in FIG. 10, the body WLb, the first end portion WLa, and the second end portion WLc of the connection line WL may be formed in the base layer 400, and the first conductor CM1 and the second conductor CM2 may also be formed in the base layer 400.

The connection line WL may include nanostructures. In an embodiment, the nanostructures may include metal-based nanostructures such as aluminum (Al), copper (Cu), silver (Ag), gold (Au), and/or platinum (Pt). In an embodiment, the nanostructures may include carbon-based nanostructures such as graphene.

In an embodiment, each of the first end portion WLa and the second end portion WLc may include first nanostructures 610. The body WLb may include second nanostructures 620 and an elastomer 630. The body WLb may have a mixed structure including the second nanostructures 620 and the elastomer 630. For example, the second nanostructures 620 may be conductive, and the elastomer 630 may be insulating.

The first and second nanostructures 610 and 620 may include metal-based nanostructures and/or carbon-based nanostructures such as graphene. Each of the first and second nanostructures 610 and 620 may include at least one of a nanowire, a nanofiber, a nanotube, a nanorod, a nanobelt, and a nanoflake. The first nanostructures 610 and the second nanostructures 620 may include the same material or may have the same shape or structure. In another example, the first nanostructures 610 and the second nanostructures 620 may include different materials or may have different shapes or structures.

Each of the first end portion WLa and the second end portion WLc may have a network structure of the first nanostructures 610. The term “network structure” refers to an interconnected or mesh-like arrangement in which individual nanostructures are not isolated, but instead overlap, cross, or contact one another to form a continuous pathway. The body WLb may be a mixed structure in which the second nanostructures 620 are arranged in the elastomer 630, and the second nanostructures 620 may contact each other in the elastomer 630 to form a network structure. A portion of the second nanostructures 620 may contact (e.g., directly contact) a portion of the first nanostructures 610 and form a network structure. A voltage or an electrical signal may be transmitted through a network structure of the first nanostructures 610, a network structure of the second nanostructures 620, and a contact and/or a network structure of the first nanostructures 610 and the second nanostructures 620, arranged in a network structure.

The connection line WL may increase an elongation of the connection line WL itself through the body WLb including the second nanostructures 620 and the elastomer 630, and may reduce resistance between the first and second lines L1 and L2 and the connection line WL through the first and second end portions WLa and WLc.

Because each of the first end portion WLa and the second end portion WLc of the connection line WL does not include an elastomer unlike the body WLb, the first nanostructures 610 of the first end portion WLa may contact (e.g., directly contact) the first line L1 and the first conductor CM1, and the first nanostructures 610 of the second end portion WLc may contact (e.g., directly contact) the second line L2 and the second conductor CM2.

The first end portion WLa may be formed by arranging the first nanostructures 610 in a network structure (e.g., an irregular network structure) rather than a plate shape having a constant thickness. Accordingly, the first conductor CM1 formed on the first end portion WLa may contact (e.g., directly contact) the first nanostructures 610 of the first end portion WLa and may contact (e.g., directly contact) the first line L1 as shown in FIG. 10. For example, the first conductor CM1 may contact (e.g., directly contact) the first nanostructures 610, and may contact (e.g., directly contact) the first line L1 while at least partially filling cavities between the first nanostructures 610 in a network structure. Electrical connection between the first nanostructures 610 of the first end portion WLa and the first line L1 may be further enhanced by the first conductor CM1. When electrical connection between the first nanostructures 610 and the first line L1 is further enhanced, it may mean that the contact resistance between the first nanostructures 610 and the first line L1 is reduced.

For example, the second end portion WLc may be formed by arranging the first nanostructures 610 in a network structure (e.g., an irregular network structure) rather than a plate shape having a constant thickness. Accordingly, the second conductor CM2 may contact (e.g., directly contact) the first nanostructures 610 of the second end portion WLc and may contact (e.g., directly contact) the second line L2 as shown in FIG. 10. For example, the second conductor CM2 may contact (e.g., directly contact) the first nanostructures 610, and may contact (e.g., directly contact) the second line L2 while at least partially filling the cavities between the first nanostructures 610 in a network structure. Electrical connection between the first nanostructures 610 of the second end portion WLc and the second line L2 may be further enhanced by the second conductor CM2. When electrical connection between the first nanostructures 610 of the second end portion WLc and the second line L2 is further enhanced, it may mean that contact resistance between the first nanostructures 610 of the second end portion WLc and the second line L2 is reduced.

In an embodiment, as shown in FIG. 10, the first conductor CM1 may include a first portion overlapping the first end portion WLa of the connection line WL and a second portion overlapping the body WLb of the connection line WL. The first portion of the first conductor CM1 may include an area in which metal elements included in the first conductor CM1 and the first nanostructures 610 are locally mixed, unlike the second portion.

For example, the second conductor CM2 may include a first portion overlapping the second end portion WLc of the connection line WL and a second portion overlapping the body WLb of the connection line WL. The first portion of the second conductor CM2 may include an area in which metal elements included in the second conductor CM2 and the first nanostructures 610 are locally mixed, unlike the second portion.

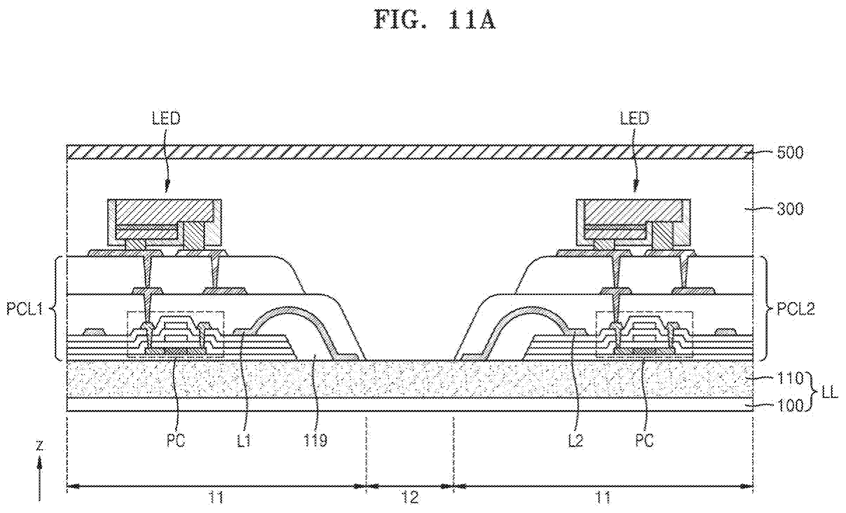

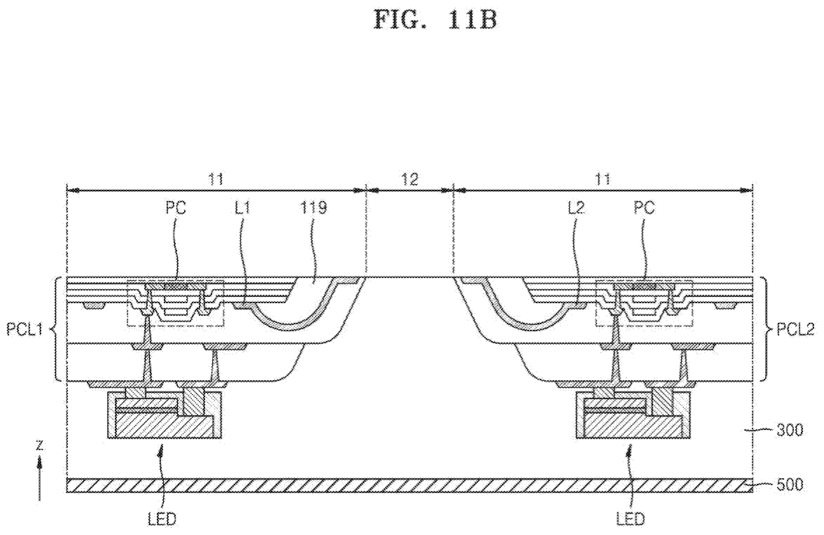

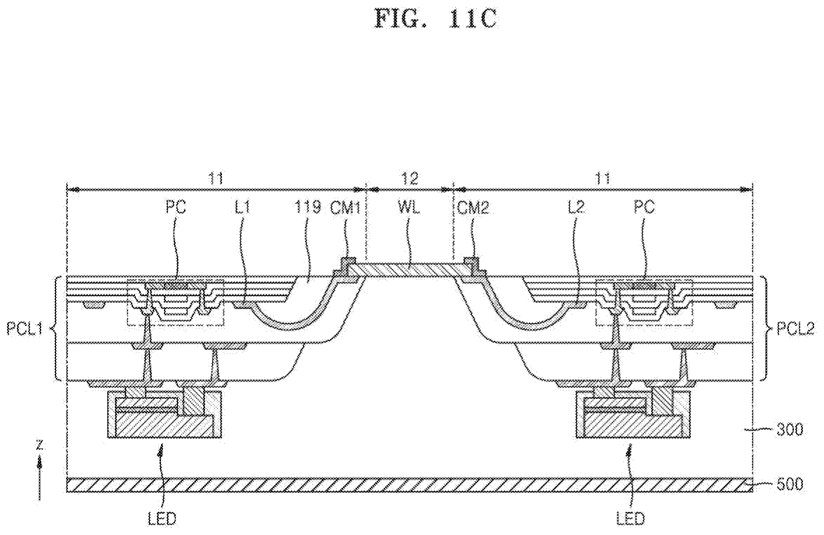

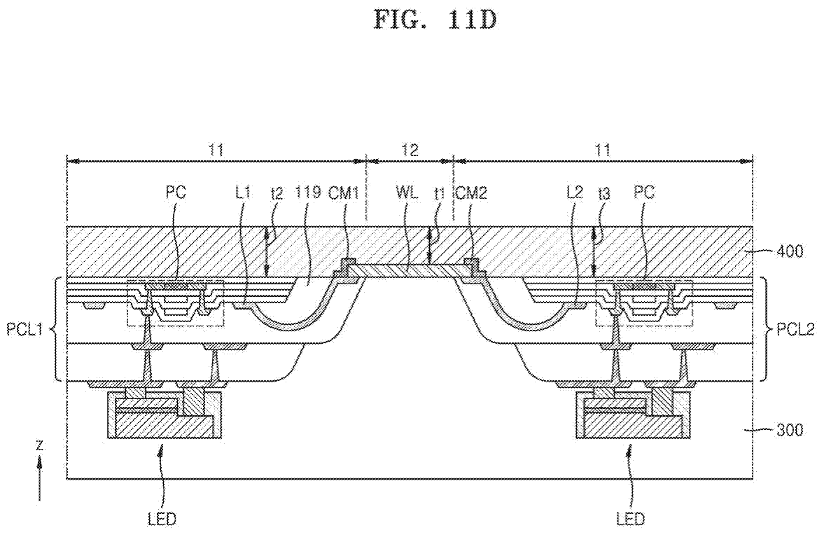

FIGS. 11A, 11B, 11C, and 11D are cross-sectional views illustrating a process of manufacturing a display panel, according to an embodiment of the disclosure.

Referring to FIG. 11A, the first pixel circuit layer PCL1 and the second pixel circuit layer PCL2 may be formed on a carrier layer LL, and the light-emitting diode LED may be formed. The carrier layer LL may include a substrate 100 and a resin layer 110 disposed on the substrate 100. The substrate 100 may be a rigid substrate. For example, the substrate 100 may be a transparent glass substrate including SiO₂ as a main component, or may be a substrate including a polymer resin material such as reinforced plastic. The resin layer 110 may include a polymer resin. Although the carrier layer LL includes two layers in FIG. 11A, the disclosure is not limited thereto. In some embodiments, the carrier layer LL may include a single layer such as including only the substrate 100 or only the resin layer 110.

Each of the first pixel circuit layer PCL1 and the second pixel circuit layer PCL2 may have a structure as described with reference to FIG. 9, and the light-emitting diode LED electrically connected to each of the first pixel circuit layer PCL1 and the second pixel circuit layer PCL2 may have a structure as described with reference to FIGS. 6A, 6B, 6C, 6D, and 6E. In a process of forming the first pixel circuit layer PCL1 and the second pixel circuit layer PCL2, the first line L1 and the second line L2 may be formed. A portion of each of the first line L1 and the second line L2 may extend onto the carrier layer LL after passing over the third organic insulating layer 119 as shown in FIG. 11A.

For example, the protective layer 300 may be formed, and a carrier film 500 may be formed on the protective layer 300. In some embodiments, an adhesive layer may be further disposed between the protective layer 300 and the carrier film 500. The carrier film 500 may protect the protective layer 300 from scratches or dents, which occur during the process. For example, the carrier film 500 may include an insulating material.

Referring to FIG. 11B, a structure formed according to the process of FIG. 11A may be inverted upside down, and then the carrier layer LL may be removed. As the carrier layer LL is removed, a surface of the first pixel circuit layer PCL1 and the second pixel circuit layer PCL2 (e.g., a surface opposite to a surface facing the light-emitting diode LED) may be exposed, and a portion (or a surface) of each of the first line L1 and the second line L2 may be exposed.

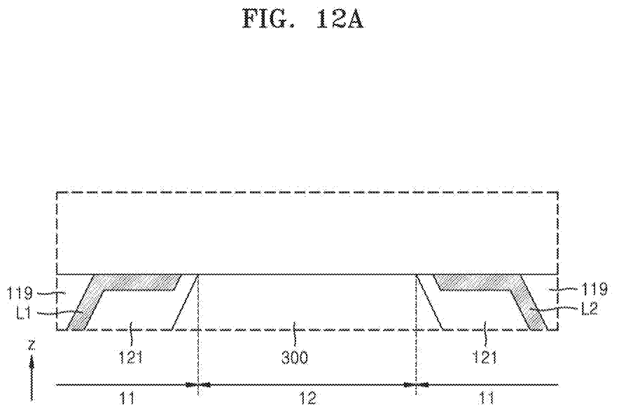

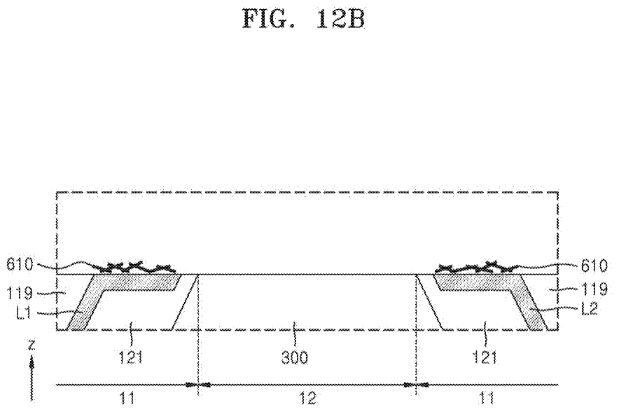

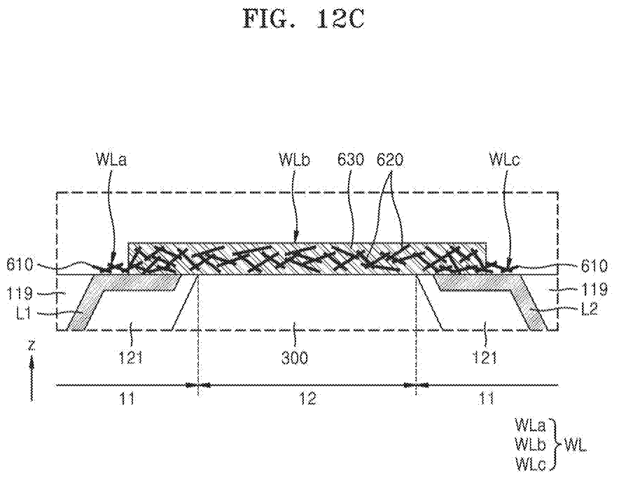

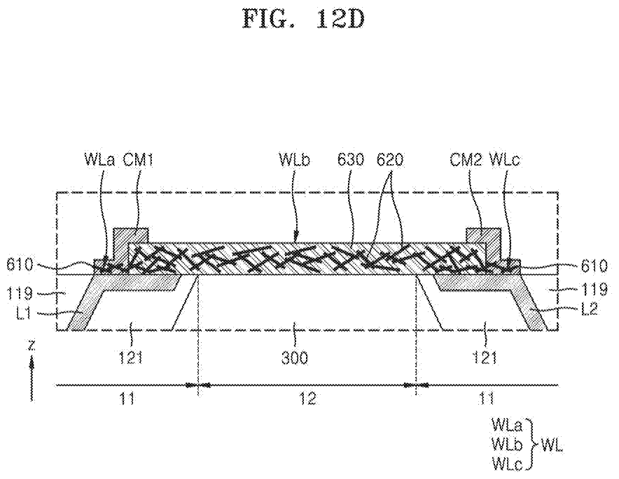

Referring to FIG. 11C, the connection line WL, the first conductor CM1, and the second conductor CM2 may be formed. FIGS. 12A, 12B, 12C, and 12D are schematic cross-sectional views illustrating a process of forming the connection line WL, the first conductor CM1, and the second conductor CM2 of FIG. 11C.

Referring to FIGS. 12A and 12B, the first nanostructures 610 may be formed on a portion of the first line L1 and a portion of the second line L2 which are exposed to the outside. The first nanostructures 610 may be formed through a process such as an inkjet printing process, a screen printing process, or a spray printing process, and may have a network structure in which the first nanostructures 610 contact each other.

The first nanostructures 610 on the portion of the first line L1 may correspond to the first end portion WLa of the connection line WL (see FIG. 11C), and the first nanostructures 610 on the portion of the second line L2 may correspond to the second end portion WLc of the connection line WL (see FIG. 11C).

Referring to FIG. 12C, a mixed structure including the second nanostructures 620 and the elastomer 630 may be formed. In an embodiment, the mixed structure may be formed through a process of printing a mixed material of the second nanostructures 620 and the elastomer 630 through a printing process such as an inkjet printing process, a screen printing process, or a spray printing process, and then curing a material corresponding to the elastomer 630. During the printing process, a portion of the second nanostructures 620 may be coated to overlap a portion of the first nanostructures 610 to contact (e.g., directly contact) a portion of the first nanostructures 610, thereby forming a network structure. The mixed structure including the second nanostructures 620 and the elastomer 630 may correspond to the body WLb of the connection line WL (see FIG. 11C).

Referring to FIG. 12D, the first and second conductors CM1 and CM2 may be formed. The first and second conductors CM1 and CM2 may be formed by forming a conductive material film on the connection line WL, and then photo-patterning and etching the conductive material film.

In a process of depositing a conductive material corresponding to the first and second conductors CM1 and CM2, the deposition material (e.g., conductive material/metal) may fill the cavities of the first nanostructures 610 in a network structure, thereby improving a mechanical coupling force by an anchoring effect, and as shown in FIG. 12D, each of the first and second conductors CM1 and CM2 may contact (e.g., directly contact) not only the first nanostructures 610 of a corresponding one of the first and second end portions WLa and WLc but also a corresponding one of the first and second lines L1 and L2. Each of the first and second conductors CM1 and CM2 may contact a part/portion of the connection line WL. The first and second conductors CM1 and CM2 may improve (or reduce) contact resistance between the connection line WL and the first and second lines L1 and L2.

Referring to FIG. 11D, the base layer 400 may be formed on a structure of FIG. 11C (e.g., a structure described with reference to FIGS. 12A to 12D). The base layer 400 may include the same material as that described with reference to FIG. 9. The base layer 400 may support components of the display panel 10 (see FIG. 9), and may absorb stress which occurs when the display panel 10 (see FIG. 9) is stretched.

After the base layer 400 is formed, the display panel 10 as shown in FIG. 9 may be formed by removing the carrier film 500. The carrier film 500 may be removed using a release tape.

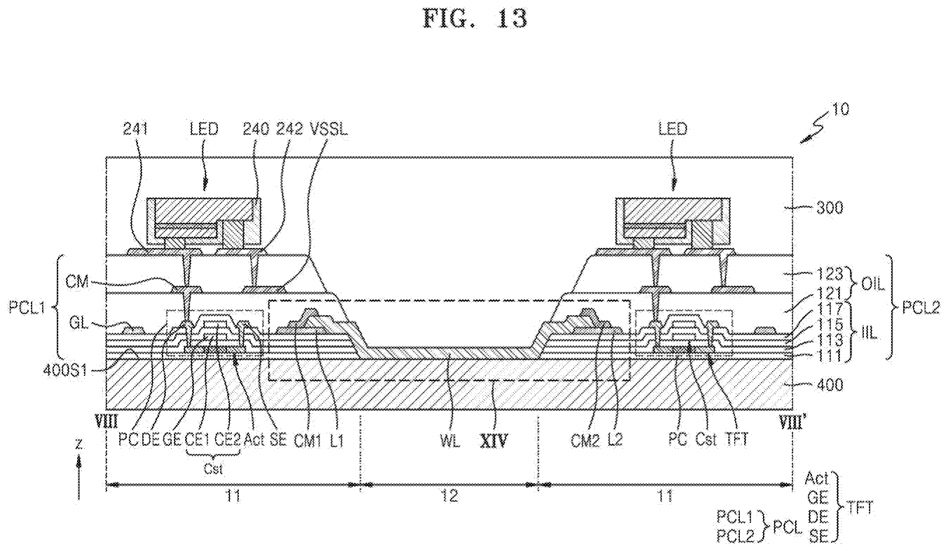

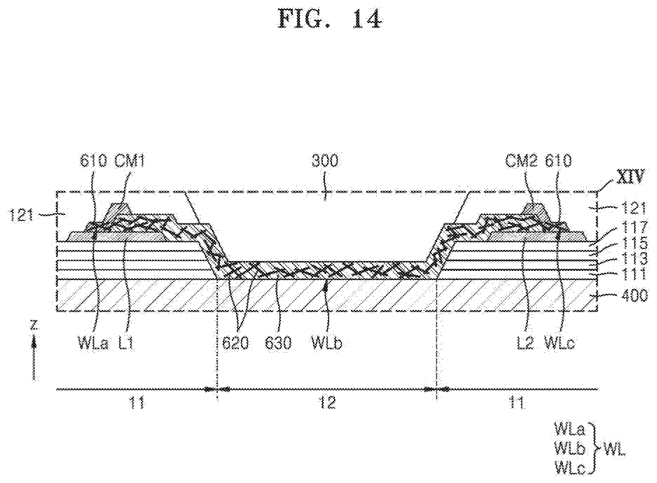

FIG. 13 is a cross-sectional view schematically illustrating a display panel, according to an embodiment of the disclosure, which corresponds to a cross-section taken along line VIII-VIII′ of FIG. 8, and FIG. 14 is an enlarged cross-sectional view illustrating a portion XIV of FIG. 13.

The display panel 10 of FIG. 13 may include the first pixel circuit layer PCL1, the second pixel circuit layer PCL2, the light-emitting diodes LED, and the protective layer 300, like the display panel 10 described with reference to FIG. 9, but differs in positions of the first line L1, the second line L2, the connection line WL, the first conductor CM1, and the second conductor CM2. In FIG. 13, the same components of the display panel 10 as those described with reference to FIG. 9 will not be described, and a difference will be described.

The first line L1 and the second line L2 may be disposed on any one insulating layer (e.g., the interlayer insulating layer 117) among insulating layers of the first and second pixel circuit layers PCL1 and PCL2, and may not extend toward the first surface 400S1 of the base layer 400.

Referring to FIGS. 13 and 14, the connection line WL may be disposed on the first surface 400S1 of the base layer 400, and may extend toward the first pixel circuit layer PCL1 and the second pixel circuit layer PCL2. The first end portion WLa of the connection line WL may extend onto the inorganic insulating stack IIL of the first pixel circuit layer PCL1 disposed in the first area 11, and the second end portion WLc of the connection line WL may extend onto the inorganic insulating stack IIL of the second pixel circuit layer PCL2 disposed in the first area 11. The first end portion WLa of the connection line WL may be disposed on a top surface (or upper surface) of the first line L1 on any one insulating layer (e.g., the interlayer insulating layer 117) of the first pixel circuit layer PCL1, and the second end portion WLc of the connection line WL may be disposed on a top surface (or upper surface) of the second line L2 on any one insulating layer (e.g., the interlayer insulating layer 117) of the second pixel circuit layer PCL2.

The first conductor CM1 may be disposed on an overlapping portion between the first end portion WLa of the connection line WL and the first line L1. The second conductor CM2 may be disposed on an overlapping portion between the second end portion WLc of the connection line WL and the second line L2. Along the thickness direction (e.g., the positive z-axis direction or the negative z-axis direction), the first end portion WLa of the connection line WL may be disposed between the first conductor CM1 and a portion of the first line L1, and the second end portion WLc may be disposed between the second conductor CM2 and a portion of the second line L2.

Each of the first end portion WLa and the second end portion WLc may include the first nanostructures 610. The body WLb may include the second nanostructures 620 and the elastomer 630. The body WLb may be a mixed structure including the second nanostructures 620, which is conductive, and the elastomer 630, which is insulating. The first and second nanostructures 610 and 620 may include metal-based nanostructures and/or carbon-based nanostructures such as graphene. Each of the first and second nanostructures 610 and 620 may include at least one of a nanowire, a nanofiber, a nanotube, a nanorod, a nanobelt, and a nanoflake. The first nanostructures 610 and the second nanostructures 620 may include the same material. In another example, the first nanostructures 610 and the second nanostructures 620 may include different materials.

The first conductor CM1 may contact (e.g., directly contact) the first nanostructures 610 of the first end portion WLa and may also contact (e.g., directly contact) the first line L1 as shown in FIG. 14. For example, the first conductor CM1 may contact (e.g., directly contact) the first nanostructures 610, and may contact (e.g., directly contact) the first line L1 while at least partially filling the cavities between the first nanostructures 610 in a network structure. Electrical connection between the first nanostructures 610 of the first end portion WLa and the first line L1 may be further enhanced by the first conductor CM1. For example, contact resistance between the first nanostructures 610 and the first line L1 may be reduced.

The first conductor CM1 may include a first portion overlapping the first end portion WLa of the connection line WL and a second portion overlapping the body WLb of the connection line WL. The first portion of the first conductor CM1 may include an area in which metal elements included in the first conductor CM1 and the first nanostructures 610 are locally mixed, unlike the second portion.

The second conductor CM2 may contact (e.g., directly contact) the first nanostructures 610 of the second end portion WLc and may contact (e.g., directly contact) the second line L2 as shown in FIG. 14. For example, the second conductor CM2 may contact (e.g., directly contact) the first nanostructures 610, and may contact (e.g., directly contact) the second line L2 while at least partially filling the cavities between the first nanostructures 610 in a network structure. Electrical connection between the first nanostructures 610 of the second end portion WLc and the second line L2 may be further enhanced by the second conductor CM2. Electrical connection between the first nanostructures 610 of the second end portion WLc and the second line L2 may be further enhanced. For example, contact resistance between the first nanostructures 610 of the second end portion WLc and the second line L2 may be reduced.

The second conductor CM2 may include a first portion overlapping the second end portion WLc of the connection line WL and a second portion overlapping the body WLb of the connection line WL. The first portion of the second conductor CM2 may include an area in which metal elements included in the second conductor CM2 and the first nanostructures 610 are locally mixed, unlike the second portion.

The organic insulating layer OIL, for example, the first organic insulating layer 121, of the first pixel circuit layer PCL1 may cover an overlapping portion (e.g., a connection portion or a contact portion) of the first line L1, the first end portion WLa of the connection line WL, and the first conductor CM1. The organic insulating layer OIL, for example, the first organic insulating layer 121, of the second pixel circuit layer PCL2 may cover an overlapping portion (e.g., a connection portion or a contact portion) of the second line L2, the second end portion WLc of the connection line WL, and the second conductor CM2.

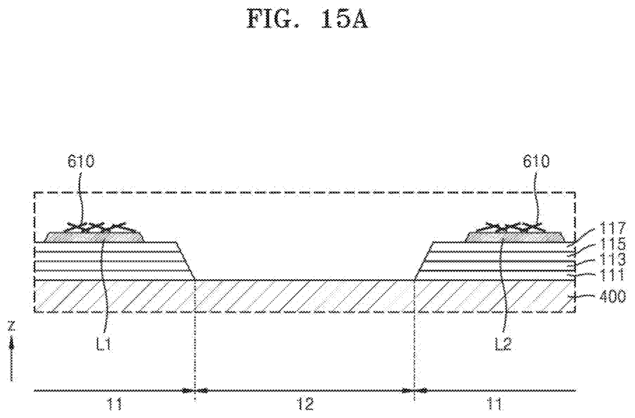

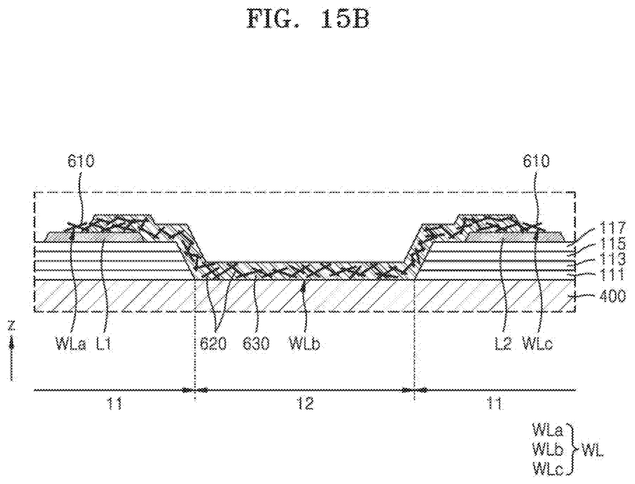

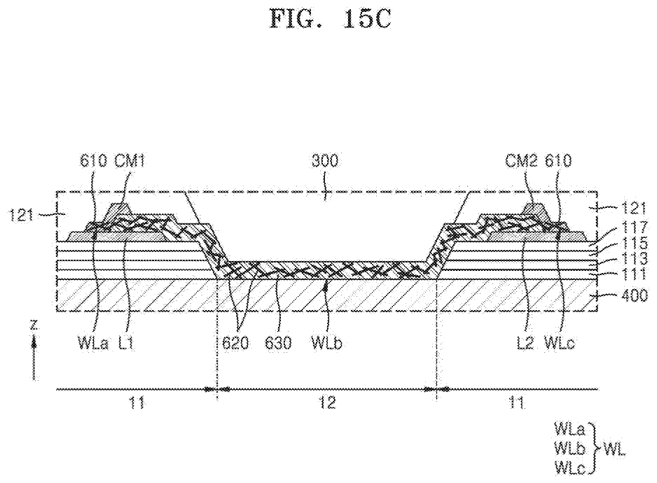

FIGS. 15A, 15B, and 15C are cross-sectional views schematically illustrating a process of manufacturing the first line L1, the second line L2, the connection line WL, the first conductor CM1, and the second conductor CM2, as described with reference to FIG. 14.

The first line L1 and the second line L2 may be formed in any one of the processes of forming the first pixel circuit layer PCL1 and the second pixel circuit layer PCL2 as described with reference to FIG. 11A. For example, the first line L1 and the second line L2 may be formed in/during a process of forming the source electrode SE (see FIG. 13) and/or the drain electrode DE (see FIG. 13).

The connection line WL, the first conductor CM1, and the second conductor CM2 may be formed before a process of forming the organic insulating layer OIL (see FIG. 13), for example, the first organic insulating layer 121.

Referring to FIG. 15A, the first nanostructures 610 may be formed on a portion of the first line L1 and a portion of the second line L2. The first nanostructures 610 may be formed through a process such as an inkjet printing process, a screen printing process, or a spray printing process. The first nanostructures 610 on the portion of the first line L1 may correspond to the first end portion WLa of the connection line WL (see FIG. 14), and the first nanostructures 610 on the portion of the second line L2 may correspond to the second end portion WLc of the connection line WL (see FIG. 14).

Referring to FIG. 15B, a mixed structure including the second nanostructures 620 and the elastomer 630 may be formed. In an embodiment, the mixed structure may be formed through a process of printing a mixed material of the second nanostructures 620 and the elastomer 630 through a printing process such as inkjet printing, screen printing or spray printing, and then curing a material corresponding to the elastomer 630. During the printing process, a portion of the second nanostructures 620 may be coated to overlap a portion of the first nanostructures 610 to contact (e.g., directly contact) a portion of the first nanostructures 610, thereby forming a network structure. The mixed structure including the second nanostructures 620 and the elastomer 630 may correspond to the body WLb of the connection line WL (see FIG. 14).

Referring to FIG. 15C, the first and second conductors CM1 and CM2 may be formed. The first and second conductors CM1 and CM2 may be formed by forming a conductive material film on the connection line WL, and then photo-patterning and etching the conductive material film.

In the process of depositing the conductive material corresponding to the first and second conductors CM1 and CM2, the deposition material (e.g., conductive material) may fill the cavities of the first nanostructures 610 in a network structure, thereby improving a mechanical coupling force by an anchoring effect, and thus, as shown in FIG. 15C, the first and second conductors CM1 and CM2 may contact (e.g., directly contact) not only the first nanostructures 610 but also a corresponding one of the first and second lines L1 and L2. Each of the first and second conductors CM1 and CM2 may contact a portion of the connection line WL. The first and second conductors CM1 and CM2 may improve (or reduce) contact resistance between the connection line WL and the first and second lines L1 and L2. After the first and second conductors CM1 and CM2 are formed, the first organic insulating layer 121 may be formed.

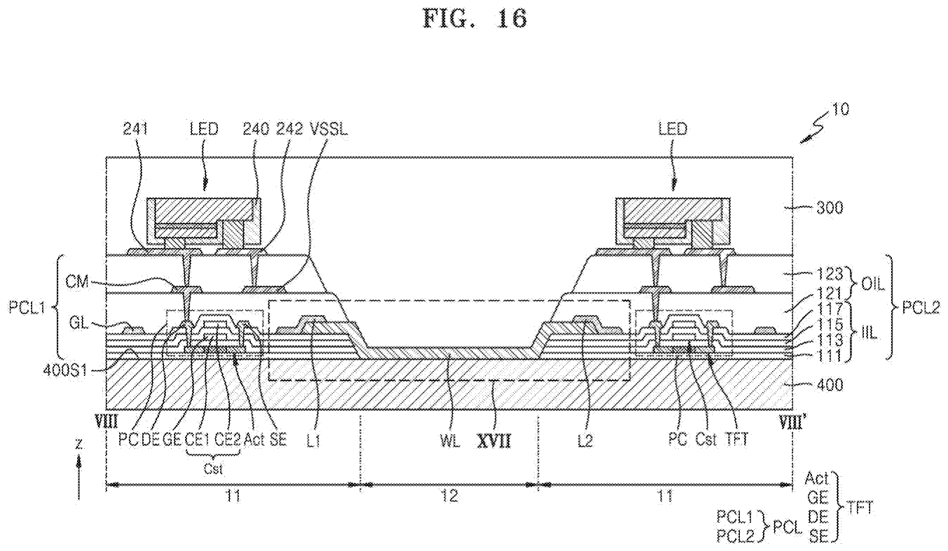

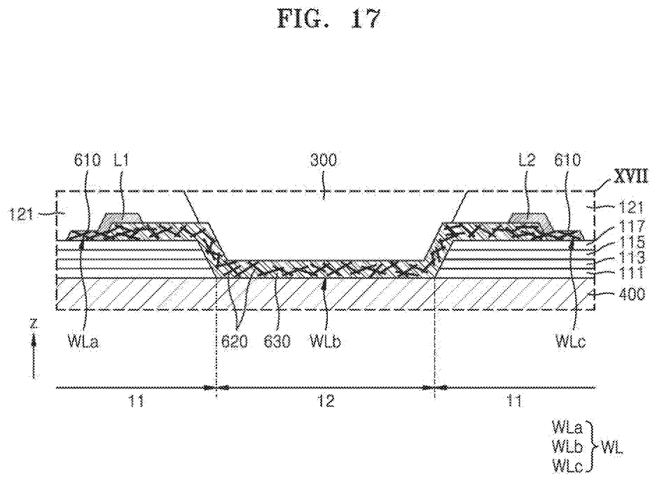

FIG. 16 is a cross-sectional view schematically illustrating a display panel 10, according to an embodiment of the disclosure, which corresponds to a cross-section taken along line VIII-VIII′ of FIG. 8, and FIG. 17 is an enlarged cross-sectional view illustrating a portion XVII of FIG. 16.

The display panel 10 of FIG. 16 may include the first pixel circuit layer PCL1, the second pixel circuit layer PCL2, the light-emitting diodes LEDs, and the protective layer 300, like the display panel 10 described with reference to FIG. 9, but differs in positions of the first line L1, the second line L2, and the connection line WL. In the display panel 10 of FIG. 9, a first end portion and a second end portion of the connection line WL may be respectively disposed on top surfaces (or upper surfaces) of the first line L1 and the second line L2 and contact resistance may be reduced by the first conductor CM1 and the second conductor CM2, whereas in the display panel 10 of FIG. 16, the first line L1 and the second line L2 may be respectively connected to a first end portion and a second end portion of the connection line WL without the first conductor CM1 and the second conductor CM2. In FIG. 16, the same components of the display panel 10 as those described with reference to FIG. 9 will not be described, and a difference will be described.

Referring to FIGS. 16 and 17, the connection line WL may be disposed on the first surface 400S1 of the base layer 400, and may extend toward the first pixel circuit layer PCL1 and the second pixel circuit layer PCL2. The body WLb of the connection line WL may be disposed on the first surface 400S1 of the base layer 400 and a side surface and a top surface (or upper surface) of the inorganic insulating stack IIL of each of the first pixel circuit layer PCL1 and the second pixel circuit layer PCL2. The first end portion WLa of the connection line WL may be disposed on the top surface of the inorganic insulating stack IIL of the first pixel circuit layer PCL1, and the second end portion WLc of the connection line WL may be disposed on the top surface of the inorganic insulating stack IIL of the second pixel circuit layer PCL2.

Each of the first end portion WLa and the second end portion WLc may include the first nanostructures 610. The body WLb may include the second nanostructures 620 and the elastomer 630. The body WLb may be a mixed structure including the second nanostructures 620, which is conductive and the elastomer 630, which is insulating. The first and second nanostructures 610 and 620 may include metal-based nanostructures and/or carbon-based nanostructures such as graphene. Each of the first and second nanostructures 610 and 620 may include at least one of a nanowire, a nanofiber, a nanotube, a nanorod, a nanobelt, and a nanoflake. The first nanostructures 610 and the second nanostructures 620 may include the same material. The first nanostructures 610 and the second nanostructures 620 may include different materials.

Each of the first end portion WLa and the second end portion WLc may have a network structure of the first nanostructures 610. The body WLb may be a mixed structure in which the second nanostructures 620 are arranged in the elastomer 630, and the second nanostructures 620 may contact each other in the elastomer 630 to form a network structure. A portion of the second nanostructures 620 may contact (e.g., directly contact) a portion of the first nanostructures 610 of each of the first end portion WLa and the second end portion WLc to form a network structure.

The first line L1 may be disposed on the first end portion WLa of the connection line WL. The first line L1 may contact (e.g., directly contact) the first nanostructures 610 of the first end portion WLa, and may contact (e.g., directly contact) an insulating layer under the first end portion WLa. For example, the first line L1 may contact (e.g., directly contact) the first nanostructures 610 of the first end portion WLa, and may contact (e.g., directly contact) a top surface (or upper surface) of an insulating layer, for example, the inorganic insulating stack IIL (e.g., a top surface of the interlayer insulating layer 117), under the first end portion WLa while at least partially filling the cavities between the first nanostructures 610 having the network structure.

The first line L1 may include a first portion overlapping the first end portion WLa of the connection line WL and a second portion overlapping the body WLb of the connection line WL as shown in FIG. 17. The first portion of the first line L1 may include an area in which metal elements which are main materials included in the first line L1 and the first nanostructures 610 are locally mixed, unlike the second portion.

The second line L2 may be disposed on the second end portion WLc of the connection line WL. The second line L2 may contact (e.g., directly contact) the first nanostructures 610 of the second end portion WLc and may contact (e.g., directly contact) an insulating layer under the second end portion WLc. For example, the second line L2 may directly contact the first nanostructures 610 of the second end portion WLc, and may contact (e.g., directly contact) a top surface (or upper surface) of an insulating layer, for example, the inorganic insulating stack IIL (e.g., a top surface of the interlayer insulating layer 117) under the second end portion WLc while at least partially filling the cavities between the first nanostructures 610 in a network structure.

The second line L2 may include a first portion overlapping the second end portion WLc of the connection line WL and a second portion overlapping the body WLb of the connection line WL as shown in FIG. 17. The first portion of the second line L2 may include an area in which metal elements which are main materials included in the second line L2 and the first nanostructures 610 are locally mixed, unlike the second portion.

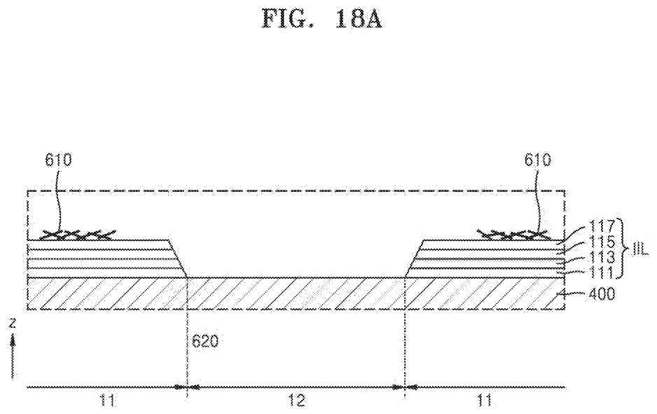

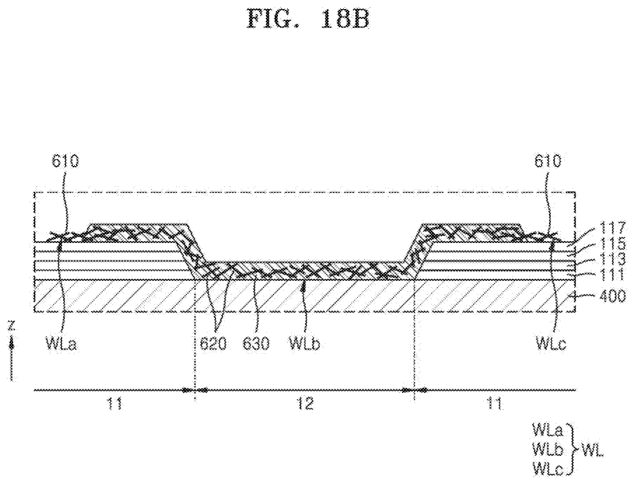

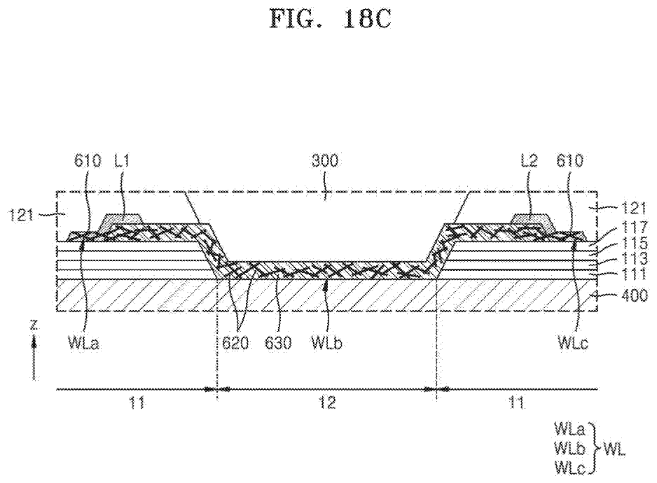

FIGS. 18A, 18B, and 18C are cross-sectional views schematically illustrating a process of manufacturing the connection line WL, the first line L1, and the second line L2 described with reference to FIG. 17.

The connection line WL, the first line L1, and the second line L2 may be formed during the processes of forming the first pixel circuit layer PCL1 and the second pixel circuit layer PCL2 as described with reference to FIG. 11A. For example, the connection line WL may be formed after the inorganic insulating stack IIL is formed.

Referring to FIG. 18A, the first nanostructures 610 may be formed on the inorganic insulating stack IIL disposed in the first area 11. The first nanostructures 610 may be formed through a process such as an inkjet printing process, a screen printing process, or a spray printing process. The first nanostructures 610 formed on the inorganic insulating stack IIL disposed in any one first area 11 may correspond to the first end portion WLa of the connection line WL (see FIG. 17), and the first nanostructures 610 formed on the inorganic insulating stack IIL disposed in another first area 11 may correspond to the second end portion WLc of the connection line WL (see FIG. 17).

Referring to FIG. 18B, a mixed structure including the second nanostructures 620 and the elastomer 630 may be formed. In an embodiment, the mixed structure may be formed through a process of printing a mixed material of the second nanostructures 620 and the elastomer 630 through a printing process such as an inkjet printing process, a screen printing process, or a spray printing process, and then curing a material corresponding to the elastomer 630. During the printing process, a portion of the second nanostructures 620 may be coated to overlap a portion of the first nanostructures 610 to contact (e.g., directly contact) a portion of the first nanostructures 610, thereby forming a network structure. The mixed structure including the second nanostructures 620 and the elastomer 630 may correspond to the body WLb of the connection line WL (see FIG. 17).

Referring to FIG. 18C, the first and second lines L1 and L2 may be formed. The first and second lines L1 and L2 may be formed by forming a conductive material film on the connection line WL, and then photo-patterning and etching the conductive material film. The first line L1 may contact portions of the first end portion WLa and the body WLb, and the second line L2 may contact portions of the second end portion WLc and the body WLb.

In a process of depositing a conductive material corresponding to the first and second lines L1 and L2, the deposition material (e.g., conductive material) may fill the cavities of the first nanostructures 610 in a network structure to improve a mechanical coupling force by an anchoring effect, and thus, as shown in FIG. 18C, each of the first and second lines L1 and L2 may contact (e.g., directly contact) not only the first nanostructures 610 but also a top surface (or upper surface) of an insulating layer, for example, the interlayer insulating layer 117, under the first nanostructures 610. Because the first and second lines L1 and L2 are directly formed on the first and second end portions WLa and WLc including the first nanostructures 610 arranged in a network structure, contact resistance between the first nanostructures 610 of the first end portion WLa and the first line L1 may be improved, and contact resistance between the first nanostructures 610 of the second end portion WLc and the second line L2 may be improved or reduced.

In the embodiment described with reference to FIG. 14, because the first nanostructures 610 of the first end portion WLa are disposed on a top surface (or upper surface) of the first line L1, which is substantially flat, contact resistance is relatively reduced, and thus, unlike the case where contact resistance between the first end portion WLa and the first line L1 is reduced by the first conductor CM1, according to the embodiment of FIGS. 18A, 18B, and 18C, contact resistance between the first end portion WLa of the connection line WL and the first line L1 may be reduced without the first conductor CM1. According to the embodiment of FIGS. 18A, 18B, and 18C, contact resistance between the second end portion WLc of the connection line WL and the second line L2 may be reduced without the second conductor CM2.

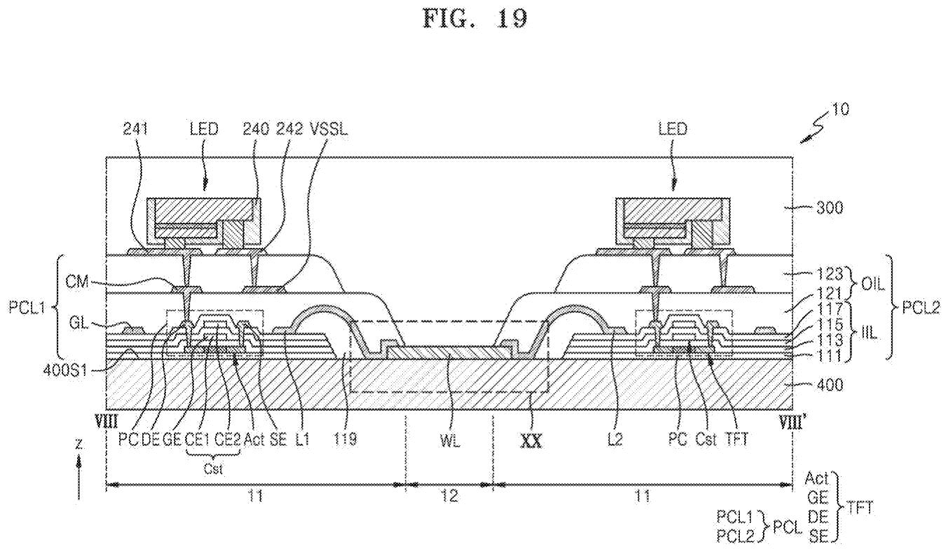

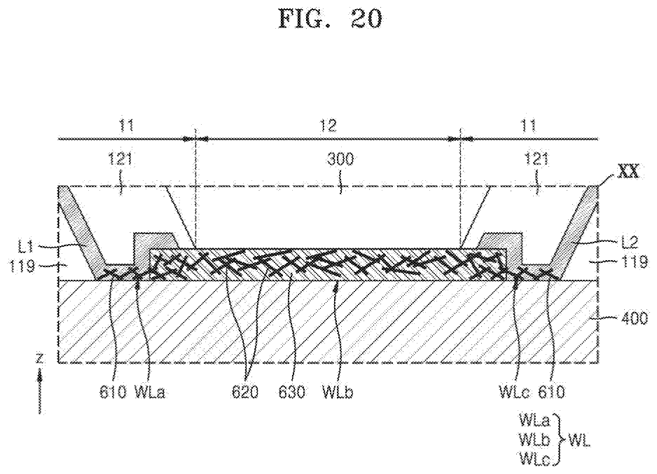

FIG. 19 is a cross-sectional view schematically illustrating a display panel, according to an embodiment of the disclosure, which corresponds to a cross-section taken along line VIII-VIII′ of FIG. 8, and FIG. 20 is an enlarged cross-sectional view illustrating a portion XX of FIG. 19.

The display panel 10 of FIG. 19 may include the first pixel circuit layer PCL1, the second pixel circuit layer PCL2, the light-emitting diodes LED, and the protective layer 300, like the display panel 10 described with reference to FIGS. 9 and 16, but differs in positions of the first line L1, the second line L2, and the connection line WL. According to the display panel 10 of FIG. 19, an overlapping portion (or a connection portion) between the connection line WL and the first line L1 and an overlapping portion (or a connection portion) between the connection line WL and the second line L2 are different from those in the embodiment of FIG. 16, and the difference will be described.

Referring to FIGS. 19 and 20, the connection line WL may be disposed on the first surface 400S1 of the base layer 400, and each of the first line L1 and the second line L2 may extend toward the first surface 400S1 of the base layer 400 so as to overlap the connection line WL. In an embodiment, although each of the first line L1 and the second line L2 extends toward the connection line WL through the third organic insulating layer 119 of each of the first and second pixel circuit layers PCL1 and PCL2, as shown in FIGS. 19 and 20, the disclosure is not limited thereto. In other embodiments, the third organic insulating layer 119 may be omitted, and each of the first line L1 and the second line L2 may extend toward the connection line WL beyond a side surface of the inorganic insulating stack IIL of each of the first and second pixel circuit layers PCL1 and PCL2.

Each of the body WLb, the first end portion WLa, and the second end portion WLc of the connection line WL may be positioned on the first surface 400S1 of the base layer 400. The first line L1 may be disposed on the first end portion WLa of the connection line WL, and the first end portion WLa may be disposed between the base layer 400 and the first line L1. The second line L2 may be disposed on the second end portion WLc of the connection line WL, and the second end portion WLc may be disposed between the base layer 400 and the second line L2.

Each of the first end portion WLa and the second end portion WLc may include the first nanostructures 610. The body WLb may include the second nanostructures 620 and the elastomer 630. The body WLb may be a mixed structure including the second nanostructures 620, which is conductive, and the elastomer 630, which is insulating. The first and second nanostructures 610 and 620 may include metal-based nanostructures and/or carbon-based nanostructures such as graphene. Each of the first and second nanostructures 610 and 620 may include at least one of a nanowire, a nanofiber, a nanotube, a nanorod, a nanobelt, and a nanoflake. The first nanostructures 610 and the second nanostructures 620 may include the same material. The first nanostructures 610 and the second nanostructures 620 may include different materials.

Each of the first end portion WLa and the second end portion WLc may have a network structure of the first nanostructures 610. The body WLb may be a mixed structure in which the second nanostructures 620 are arranged in the elastomer 630, and the second nanostructures 620 may contact each other in the elastomer 630 to form a network structure. A portion of the second nanostructures 620 may contact (e.g., directly contact) a portion of the first nanostructures 610 of each of the first end portion WLa and the second end portion WLc to form a network structure.

The first line L1 may be disposed on the first end portion WLa of the connection line WL. The first line L1 may contact (e.g., directly contact) the first nanostructures 610 of the first end portion WLa and may contact (e.g., directly contact) the base layer 400 under the first end portion WLa. For example, the first line L1 may contact (e.g., directly contact) the first nanostructures 610 of the first end portion WLa, and may contact (e.g., directly contact) the first surface 400S1 (see FIG. 19) of the base layer 400 under the first end portion WLa while at least partially filling the cavities between the first nanostructures 610 in a network structure.

The first line L1 may include a first portion overlapping the first end portion WLa of the connection line WL and a second portion overlapping the body WLb of the connection line WL as shown in FIG. 20. The first portion of the first line L1 may include an area in which metal elements which are main materials included in the first line L1 and the first nanostructures 610 are locally mixed, unlike the second portion.

The second line L2 may be disposed on the second end portion WLc of the connection line WL. The second line L2 may contact (e.g., directly contact) the first nanostructures 610 of the second end portion WLc and may contact (e.g., directly contact) the base layer 400 under the second end portion WLc. For example, the second line L2 may contact (e.g., directly contact) the first nanostructures 610 of the second end portion WLc, and may contact (e.g., directly contact) the first surface 400S1 (see FIG. 19) of the base layer 400 under the second end portion WLc while at least partially filling the cavities between the first nanostructures 610 in a network structure.

The second line L2 may include a first portion overlapping the second end portion WLc of the connection line WL and a second portion overlapping the body WLb of the connection line WL as shown in FIG. 20. The first portion of the second line L2 may include an area in which metal elements included in the second line L2 and the first nanostructures 610 are locally mixed, unlike the second portion.

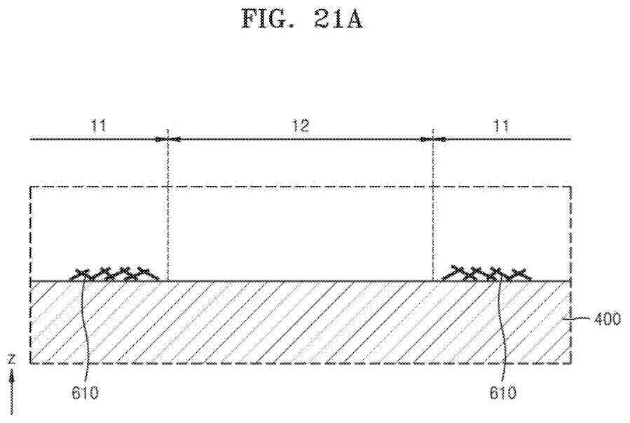

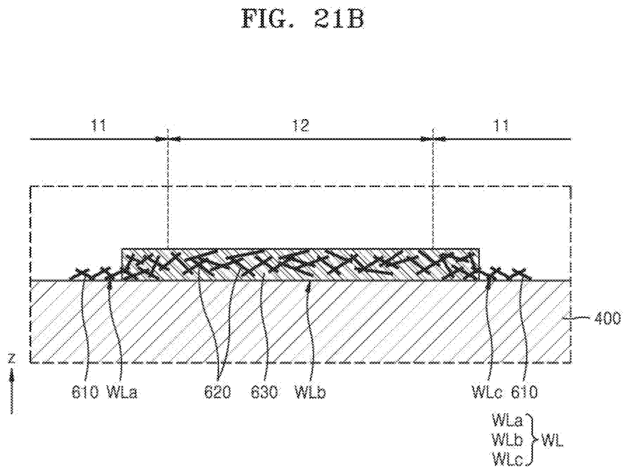

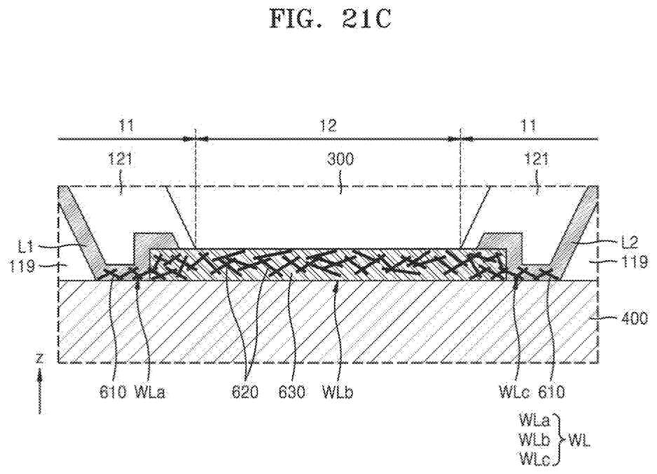

FIGS. 21A, 21B, and 21C are cross-sectional views schematically illustrating a process of manufacturing the connection line WL, the first line L1, and the second line L2 described with reference to FIG. 20.

The connection line WL, the first line L1, and the second line L2 may be formed during processes of forming the first pixel circuit layer PCL1 and the second pixel circuit layer PCL2 as described with reference to FIG. 11A. For example, the connection line WL may be formed after the inorganic insulating stack IIL is formed.

Referring to FIG. 21A, the first nanostructures 610 may be formed on the base layer 400. The first nanostructures 610 may be formed in the second area 12, and may be formed through a process such as an inkjet printing process, a screen printing process, or a spray printing process. A portion of the first nanostructures 610 may correspond to the first end portion WLa of the connection line WL (see FIG. 20), and other portion of the first nanostructures 610 may correspond to the second end portion WLc of the connection line WL (see FIG. 20).

Referring to FIG. 21B, a mixed structure including the second nanostructures 620 and the elastomer 630 may be formed. In an embodiment, the mixed structure may be formed through a process of printing a mixed material of the second nanostructures 620 and the elastomer 630 through a printing process such as an inkjet printing process, a screen printing process, or a spray printing process, and then curing a material corresponding to the elastomer 630. During the printing process, the second nanostructures 620 may be coated to overlap the first nanostructures 610 to contact (e.g., directly contact) the first nanostructures 610, thereby forming a network structure. The mixed structure including the second nanostructures 620 and the elastomer 630 may correspond to the body WLb of the connection line WL (see FIG. 17).

Referring to FIG. 21C, the first and second lines L1 and L2 may be formed. The first and second lines L1 and L2 may be formed by forming a conductive material film on the connection line WL, and then photo-patterning and etching the conductive material film. The first line L1 may contact portions of the first end portion WLa and the body WLb, and the second line L2 may contact portions of the second end portion WLc and the body WLb.

In the process of depositing the conductive material corresponding to the first and second lines L1 and L2, the deposition material (e.g., conductive material) may fill the cavities of the first nanostructures 610 in a network structure to improve a mechanical coupling force by an anchoring effect, and thus, as shown in FIG. 21C, each of the first and second lines L1 and L2 may contact (e.g., directly contact) not only the first nanostructures 610 but also the base layer 400 under the first nanostructures 610. Because the first and second lines L1 and L2 are directly formed on the first and second end portions WLa and WLc including the first nanostructures 610 arranged in a network structure, contact resistance between the first nanostructures 610 of the first end portion WLa and the first line L1 may be improved, and the contact resistance between the first nanostructures 610 of the second end portion WLc and the second line L2 may be improved or reduced.

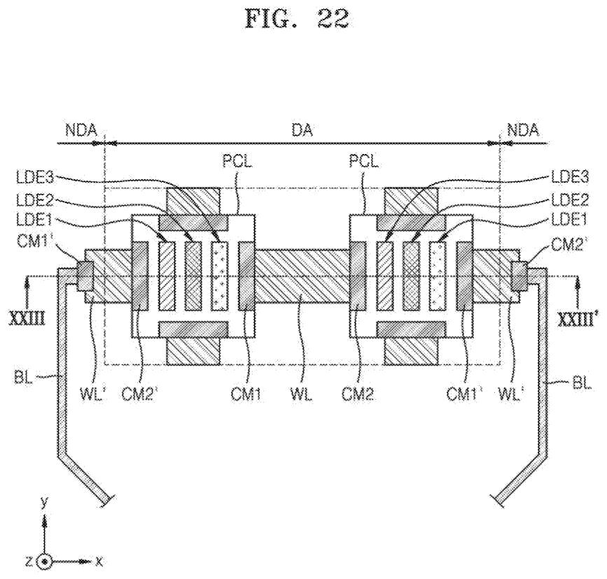

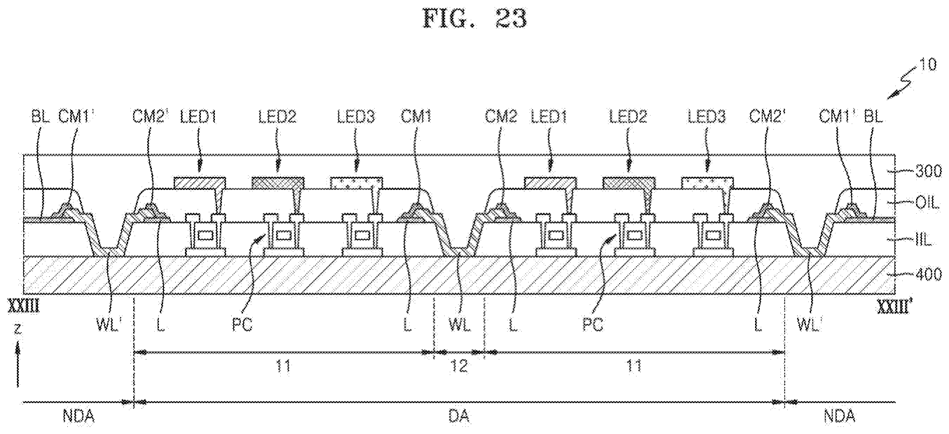

FIG. 22 is a plan view schematically illustrating the display panel 10 according to an embodiment of the disclosure, and FIG. 23 is a cross-sectional view taken along line XXIII-XXIII′ of FIG. 22.

Referring to FIG. 22, in the display area DA, the pixel circuit layers PCL may be spaced apart from each other, and light-emitting diodes, for example, first to third light-emitting diodes LED1, LED2, and LED3, may be disposed on each of the pixel circuit layers PCL. As shown in FIG. 23, the lines L electrically connected to the pixel circuits PC (see FIG. 23) of adjacent pixel circuit layers PCL may be electrically connected to each other through the connection line WL.

The lines L may include a signal line or a voltage line. For example, the line L may receive a signal from a driver through an outer line BL disposed in the non-display area NDA, or may receive a voltage from a power supply line disposed in the non-display area NDA. The outer line BL may be electrically connected to the lines L through an outer connection line WL′.

In an embodiment, in FIG. 23, adjacent lines L may be electrically connected to the connection line WL, and contact resistance is reduced through the first and second conductors CM1 and CM2. The outer line BL may be electrically connected to an outermost line L in the display area DA, and contact resistance may be reduced through first and second outer conductors CM1′ and CM2′.

The outer line BL and the lines L may be formed through the same process and may include the same material. The outer connection line WL′ and the connection line WL may be formed through the same process and may include the same material and structure. The outermost line L in the display area DA and the outer line BL may be electrically connected to the outer connection line WL′, and contact resistance may be reduced through the first and second outer conductors CM1′ and CM2′.

In FIG. 23, although the lines L, the connection line WL, and the first and second conductors CM1 and CM2 include the structure described with reference to FIGS. 13 and 14, the disclosure is not limited thereto. In other embodiments, the lines L, the connection line WL, and the first and second conductors CM1 and CM2 may include the structure described with reference to FIGS. 9 and 10. In other embodiments, the lines L and the connection line WL may include the structure described with reference to FIGS. 16 and 17, or may include the structure described with reference to FIGS. 19 and 20.

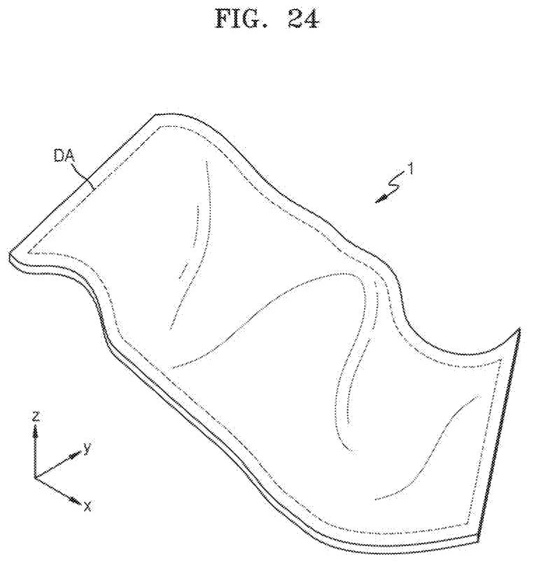

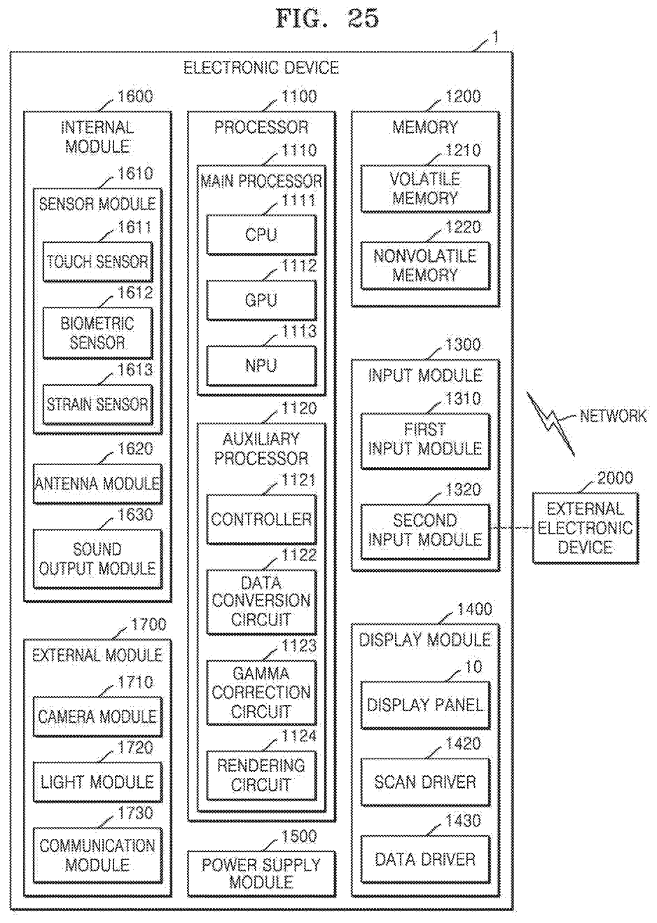

FIG. 24 is a perspective view schematically illustrating an embodiment of an electronic device 1 including a display panel, according to an embodiment of the disclosure, and FIG. 25 is a block diagram illustrating the electronic device 1 including the display panel 10, according to an embodiment of the disclosure.

Referring to FIG. 24, the electronic device 1 may be freely deformed three-dimensionally and may provide a three-dimensional (3D) image surface through the display area DA. An operation in which the electronic device 1 is freely deformed three-dimensionally is distinguished from an operation of an electronic device having a rollable display panel, such as an operation in which a portion of a display area that was rolled up is visible to a user and then another portion of the rolled display area is unfolded, thereby making the entire display area visible to the user (or an operation in which the entire display area that was unfolded is visible to the user and then the display area is rolled up, thereby making only a portion of the display area visible to the user). The electronic device 1 according to embodiments of the disclosure may be deformed so that the total area of the display area DA increases or decreases as the electronic device 1 is deformed in the first direction, the second direction, and/or the third direction.

Referring to FIG. 25, the electronic device 1 may include a processor 1100, a memory 1200, an input module 1300, a display module 1400, a power supply module 1500, an internal module 1600, and an external module 1700. According to an embodiment, in the electronic device 1, at least one of the above components may be omitted or one or more other components may be added. According to an embodiment, some of the above components (e.g., the internal module 1600) may be integrated into another component (e.g., the display module 1400).

The processor 1100 may control another component (e.g., hardware or software component) of the electronic device 1 connected to the processor 1100 by executing software and may perform various data processing or calculation. According to an embodiment, as at least portion of data processing or calculation, the processor 1100 may store a command or data received from another component (e.g., the input module 1300, a sensor module 1610, or a communication module 1730) in a volatile memory 1210, may process the command or the data stored in the volatile memory 1210, and may store result data in a nonvolatile memory 1220.

The processor 1100 may include a main processor 1110 and an auxiliary processor 1120. The main processor 1110 may include at least one of a central processing unit (CPU) 1111 and an application processor (AP). The main processor 1110 may further include at least one of a graphics processing unit (GPU) 1112, a communication processor (CP), and an image signal processor (ISP). The main processor 1110 may further include a neural processing unit (NPU) 1113. The NPU may be a processor specialized in processing an artificial intelligence (AI) model, and the AI model may be generated through machine learning. The AI model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination thereof. However, embodiments are not limited thereto. The AI model may include a software structure, in addition or alternatively, to a hardware structure. Among the above processing units and processors, at least two may be integrated into one unit (e.g., a single chip) or each may be implemented as independent units (e.g., a plurality of chips).

The auxiliary processor 1120 may include a controller 1121. The controller 1121 may include an interface conversion circuit and a timing control circuit. The controller 1121 may receive an image signal from the main processor 1110, may covert a data format of the image signal to meet the interface specification of the display module 1400, and may output image data. The controller 1121 may output various control signals necessary for driving the display module 1400.

The auxiliary processor 1120 may further include a data processing circuit such as a data conversion circuit 1122, a gamma correction circuit 1123, and a rendering circuit 1124. The data conversion circuit 1122 may receive image data from the controller 1121, and may compensate for the image data so that an image may be displayed at a desired luminance according to characteristics of the electronic device 1 or a user's settings, or may convert the image data to reduce power consumption or afterimage effects. The gamma correction circuit 1123 may convert image data or a gamma reference voltage so that an image displayed on the electronic device 1 has desired gamma characteristics. The rendering circuit 1124 may receive image data from the controller 1121, and may render the image data by considering a pixel arrangement of the display panel 10 applied to the electronic device 1. At least one of the data conversion circuit 1122, the gamma correction circuit 1123, and the rendering circuit 1124 may be integrated into another component (e.g., the main processor 1110 or the controller 1121). In an embodiment, the auxiliary processor 1120 may be integrated into a data driver 1430.

The memory 1200 may store various data used by at least one component (e.g., the processor 1100 or the sensor module 1610) of the electronic device 1, and input data or output data for commands associated with the various data. The memory 1200 may include at least one of the volatile memory 1210 and the nonvolatile memory 1220.

The input module 1300 may receive a command or data to be used in components (e.g., the processor 1100, the sensor module 1610, or a sound output module 1630) of the electronic device 1 from outside the electronic device 1 (e.g., from a user or an external electronic device 2000).

The input module 1300 may include a first input module 1310 to which a command or data is input from the user and a second input module 1320 to which a command or data is input from the external electronic device 2000.

The first input module 1310 may include a microphone, a mouse, a keyboard, or a pen (e.g., a passive pen or an active pen). The first input module 1310 may include a mechanical input means such as a button, a dome switch, a jog wheel, or a jog switch positioned on a rear surface or a side surface of the electronic device 1, or a touch input means. The touch input means may include a touchscreen layer of the display panel 10.

The second input module 1320 may be connected to various types of external electronic devices 2000 connected to the electronic device 1, by wire or wirelessly. According to an embodiment, the second input module 1320 may include a high-definition multimedia interface (HDMI), a universal serial bus (USB) interface, an SD card interface, or an audio interface. The second input module 1320 may include a connector for physically connecting the electronic device 1 to the external electronic device 2000, for example, an HDMI connector, a USB connector, an SD card connector, or an audio connector (e.g., a headphone connector). In response to the external electronic device 2000 being connected to the second input module 1320, the electronic device 1 may perform appropriate control operations related to the connected external electronic device 2000.

The display module 1400 may visually provide information to the user. The display module 1400 may include the display panel 10, a scan driver 1420, and the data driver 1430.

The display panel 10 may display or output information processed by the electronic device 1. The display panel 10 may display execution screen information of an application driven by the electronic device 1 or user interface (UI) or graphical user interface (GUI) information according to the execution screen information.

The scan driver 1420 may be mounted as a driving chip on the display panel 10. In another example, the scan driver 1420 may be formed (e.g., directly formed) on the display panel 10. For example, the scan driver 1420 may include an amorphous silicon TFT gate driver circuit (ASG), a low-temperature polycrystalline silicon (LTPS) TFT gate driver circuit, or an oxide semiconductor TFT gate driver circuit (OSG) built in the display panel 10. The scan driver 1420 may receive a control signal from the controller 1121, and may outputs scan signals to the display panel 10 in response to the control signal.

The display panel 10 may further include an emission control driver. The emission control driver may output an emission control signal to the display panel 10 in response to a control signal received from the controller 1121. The emission control driver may be formed separately from the scan driver 1420 or may be integrated into the scan driver 1420.

The data driver 1430 may receive a control signal from the controller 1121, may convert image data into a data voltage that is an analog voltage in response to the control signal, and then may output data voltages to the display panel 10.

The data driver 1430 may be integrated with some components of the auxiliary processor 1120. For example, the data driver 1430 may be provided as a timing controller embedded driver IC including the controller 1121.

The power supply module 1500 may supply power to components of the electronic device 1. The power supply module 1500 may include a battery that charges a power supply voltage. For example, the power supply module 1500 may include a connection port, and the connection port may be included in the second input module 1320 to which an external charger for supplying power is connected to charge the battery. In another example, the power supply module 1500 may include a wireless power transmission/reception unit to charge the battery in a wireless manner. The wireless power transmission/reception unit may include a plurality of antenna radiators in the form of coils. The power supply module 1500 may include a power management integrated circuit (PMIC). The PMIC may supply optimized power to each of the components of the electronic device 1.

The electronic device 1 may further include the internal module 1600 and the external module 1700. The internal module 1600 may include the sensor module 1610, an antenna module 1620, and the sound output module 1630. The external module 1700 may include a camera module 1710, a light module 1720, and/or the communication module 1730.

The sensor module 1610 may include touch electrodes of the touchscreen layer of the display panel 10 and a touch sensor driver. The sensor module 1610 may detect an input by the user's body part or an input by a pen, and may generate an electrical signal or a data value corresponding to the input. The sensor module 1610 may include at least one of a touch sensor 1611, a biometric sensor 1612, and a strain sensor 1613.

The touch sensor 1611 may generate a data value corresponding to coordinate information of an input by the user's body part (e.g., a finger) or an input by a pen. The touch sensor 1611 may detect a capacitance change, a pressure change, or an electromagnetic change due to an input as a data value.

The biometric sensor 1612 may generate a data value for recognizing the user's body part (e.g., fingerprint, iris, or face) or a data value corresponding to body information (e.g., blood pressure, moisture, heart rate, or body composition). The biometric sensor 1612 may operate using an optical method, an ultrasonic method, or a capacitive method.

The strain sensor 1613 may include a layer, a pattern, or wirings whose measurable physical quantity varies according to stretching of the display panel 10. For example, the strain sensor 1613 may include wirings whose resistance and/or capacitance is changed by stretching of the display panel 10. In other embodiments, the strain sensor 1613 may include an optical layer or an optical pattern whose transmittance and/or reflectance is changed by stretching of the display panel 10.

The electronic device 1 may improve the quality of an image displayed on the display panel 10 or control the display panel 10 based on a change in a physical quantity according to stretching of the display panel 10 measured by the strain sensor 1613. A control operation of the display panel 10 may include, for example, an operation of displaying an operation image for protecting the display panel 10, blocking a voltage for driving the display panel 10, or stopping a stretching operation of the display panel 10.

In an embodiment, at least one of the touch sensor 1611, the biometric sensor 1612, and the strain sensor 1613 may be embedded in the display panel 10. For example, at least one of the touch sensor 1611, the biometric sensor 1612, and the strain sensor 1613 may be formed through a process continuous with a process of forming a pixel driving circuit unit and a light-emitting element of the display panel 10. Accordingly, the display panel 10 may function as one of the input modules 1300 that provide an input interface between the electronic device 1 and the user and may also function as the display module 1400 that provides an output interface between the electronic device 1 and the user.

In an embodiment, at least two of the touch sensor 1611, the biometric sensor 1612, and the strain sensor 1613 may be integrated into one sensing panel through the same process. In an embodiment, the sensing panel may be disposed between the display panel 10 and a window cover disposed on a front surface of the display panel 10, but the disclosure is not limited thereto.

The antenna module 1620 may include one or more antennas for transmitting a signal or power to the outside or receiving a signal or power from the outside. According to an embodiment, the communication module 1730 may transmit a signal to an external electronic device or may receive a signal from an external electronic device through an antenna suitable for a communication method. An antenna pattern of the antenna module 1620 may be integrated into one component (e.g., the display panel 10) of the display module 1400 or the biometric sensor 1612.

The sound output module 1630 may be a device for outputting a sound signal to the outside of the electronic device 1 and may output sound data received from the communication module 1730 or stored in the memory 1200 in a call signal reception mode, a call mode, a recording mode, a voice recognition mode, or a broadcast reception mode. The sound output module 1630 may output a sound signal related to a function (e.g., a call signal reception sound or a message reception sound) performed in the electronic device 1. The sound output module 1630 may include a receiver and a speaker. At least one of the receiver and the speaker may be a sound generating device that is attached to the bottom of the display panel 10 and outputs sound by vibrating the display panel 10. The sound generating device may be a piezoelectric element or a piezoelectric actuator that contracts or expands according to an electrical signal, or an exciter that generates a magnetic force using a voice coil and vibrates the display panel 10.

The camera module 1710 may capture a still image and a moving image. According to an embodiment, the camera module 1710 may include one or more lenses, an image sensor, or an image signal processor. The camera module 1710 may further include an infrared camera for measuring the presence or absence of the user, a location of the user, and a gaze of the user.

The light module 1720 may output a signal for notifying the occurrence of an event using light of a light source, or may provide light for obtaining an image. Examples of the event may include message reception, call signal reception, missed call, alarm, schedule notification, email reception, and battery charging capacity information notification. The light module 1720 may include a light-emitting diode (LED) or a xenon-lamp. The light module 1720 may emit light of a single color or multiple colors to a front surface or a rear surface of the electronic device 1. The light module 1720 may interoperate with the camera module 1710 or may operate independently.

The communication module 1730 may support establishing a wired or wireless communication channel between the electronic device 1 and the external electronic device 2000, and may perform communication through the established communication channel. The communication module 1730 may include one or both of a wireless communication module and a wired communication module. The wireless communication module may include a cellular communication module, a short-range wireless communication module, or a global navigation satellite system (GNSS) communication module. The wired communication module may include a local area network (LAN) communication module or a power line communication module. The communication module 1730 may transmit and receive a wireless signal on the Internet using at least one of wireless LAN (WLAN), wireless-fidelity (Wi-Fi), Wi-Fi Direct™, and digital living network alliance (DLNA). For example, the communication module 1730 may support short-range communication using at least one of Bluetooth™, radio frequency identification (RFID), infrared data association (IrDA), ultra-wideband (UWB), ZigBee, near-field communication (NFC), Wi-Fi, Wi-Fi Direct™, and wireless universal serial bus (USB). The various types of communication modules 1730 described above may be implemented as one chip or may be implemented as separate chips.

Although the display panel 10 is included in the electronic device 1 that provides an image surface that is three-dimensionally deformable by being three-dimensionally freely deformed in the embodiment described with reference to FIG. 24, the disclosure is not limited thereto. As shown in FIGS. 24 and 25, an electronic device may include an image providing area having a fixed shape, and a display panel may be disposed in the image providing area of the electronic device in a process of manufacturing the electronic device. The display panel may be fixed to the electronic device in a three-dimensionally deformable state.

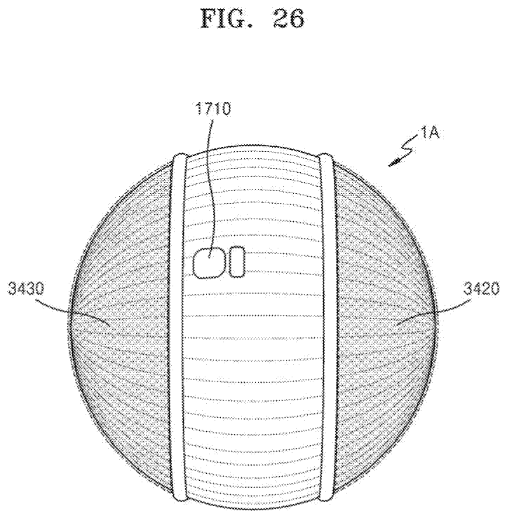

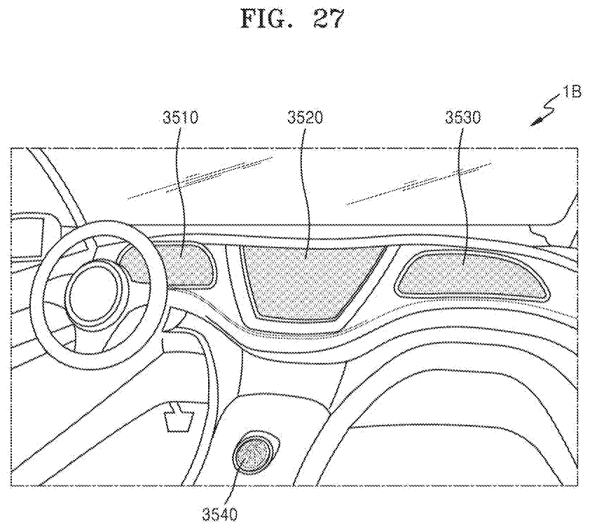

FIGS. 26 and 27 are perspective views illustrating an electronic device, according to an embodiment of the disclosure.

FIG. 26 illustrates a robot as an electronic device 1A, according to an embodiment. The robot may recognize movement or an object using a camera module 1710, and may display a certain image to a user through display units 3420 and 3430. In some embodiments, because display panels according to an embodiment of the disclosure may be stretched in various directions as described above, the display panels may be assembled to a frame of an electronic device 1A while being three-dimensionally stretched along a hemispherical body frame, thereby forming the display units 3420 and 3430.

FIG. 27 illustrates a display device for a vehicle as an electronic device 1B, according to an embodiment of the disclosure. The display device for the vehicle may include a cluster 3510, a center information display (CID) 3520, and/or a co-driver display (passenger display). Because a display panel according to an embodiment may be stretched in various directions, the display panel may be applied to the cluster 3510, the CID 3520, and/or the passenger display (co-driver display) regardless of a shape of an internal frame of a vehicle.

Although the cluster 3510, the CID 3520, and/or the co-driver display are separated from each other in FIG. 27, the disclosure is not limited thereto. In other embodiments, two or more selected from the cluster 3510, the CID 3520, and the co-driver display may be integrally connected.

In some embodiments, the display device for the vehicle may include a button 3540 for displaying a certain image. The button 3540 may have a hemispherical shape, and may sense a touch input of a user (e.g., a driver) in the positive z-axis direction or the negative z-axis direction.

Although the electronic devices 1A and 1B are used in a robot or a vehicle in FIGS. 26 and 27, the disclosure is not limited thereto. An electronic device of the disclosure may include electronic devices for various purposes such as a commercial electronic device, an office electronic device, an educational electronic device, a wearable electronic device, or a medical electronic device. In other words, a display panel according to an embodiment of the disclosure may be provided in any of various electronic devices as long as it includes an area in which an image may be provided.

According to some embodiments of the disclosure, a display panel and an electronic device having excellent electrical characteristics and elongation characteristics may be provided. The effects described above are examples, and the effects of the disclosure are not limited thereto.

While the disclosure has been particularly shown and described with reference to embodiments thereof, they are provided for the purposes of illustration and it will be understood by one of ordinary skill in the art that various modifications and equivalent other embodiments made be made from the disclosure. Accordingly, the true technical scope of the disclosure is defined by the technical spirit of the appended claims.

What is claimed is:

1. A display panel comprising:
a base layer comprising a first surface and a second surface opposite to the first surface;
a first pixel circuit layer on the first surface of the base layer and comprising a transistor and insulating layers;
a second pixel circuit layer on the first surface of the base layer, spaced apart from the first pixel circuit layer, and comprising a transistor and insulating layers;
a first light-emitting diode on the first pixel circuit layer and configured to be electrically connected to the transistor of the first pixel circuit layer;
a second light-emitting diode on the second pixel circuit layer and configured to be electrically connected to the transistor of the second pixel circuit layer;
a first line configured to be electrically connected to the transistor of the first pixel circuit layer;
a second line configured to be electrically connected to the transistor of the second pixel circuit layer;
a connection line configured to electrically connect the first line and the second line, and comprising nanostructures, a first end portion overlapping the first line, and a second end portion overlapping the second line;
a first conductor on a first overlapping portion between the first line and the first end portion of the connection line; and
a second conductor on a second overlapping portion between the second line and the second end portion of the connection line.

2. The display panel of claim 1, wherein the nanostructures comprise metal-based nanostructures.

3. The display panel of claim 1, wherein the nanostructures comprise first nanostructures and second nanostructures,
the connection line comprises a body between the first end portion and the second end portion,
wherein each of the first end portion and the second end portion comprises the first nanostructures, and
the body comprises the second nanostructures configured to be electrically connected to the first nanostructures, and an elastomer,
wherein a portion of the second nanostructures overlap and contact a portion of the first nanostructures.

4. The display panel of claim 3, wherein each of the first nanostructures and the second nanostructures comprises at least one of a nanowire, a nanofiber, a nanotube, a nanorod, a nanobelt, and a nanoflake.

5. The display panel of claim 3, wherein the first conductor directly contacts the first nanostructures of the first end portion of the connection line, directly contacts a portion of the first line, and at least partially fills a cavity between the first nanostructures in a network structure, and
wherein the second conductor directly contacts the first nanostructures of the second end portion of the connection line, directly contacts a portion of the second line, and at least partially fills a cavity between the first nanostructures arranged in a network structure.

6. The display panel of claim 1, wherein each of the connection line, the first conductor, and the second conductor is in a concave portion that is recessed from the first surface of the base layer.

7. The display panel of claim 1, wherein the first conductor contacts the first overlapping portion between the first line and the first end portion on an upper surface of at least one of the insulating layers of the first pixel circuit layer, and
wherein the second conductor contacts the second overlapping portion between the second line and the second end portion on an upper surface of at least one of the insulating layers of the second pixel circuit layer.

8. A display panel comprising:
a base layer comprising a first surface and a second surface opposite to the first surface;
a first pixel circuit layer on the first surface of the base layer and comprising a transistor and insulating layers;
a second pixel circuit layer on the first surface of the base layer, spaced apart from the first pixel circuit layer, and comprising a transistor and insulating layers;
a first light-emitting diode on the first pixel circuit layer and configured to be electrically connected to the transistor of the first pixel circuit layer;
a second light-emitting diode on the second pixel circuit layer and configured to be electrically connected to the transistor of the second pixel circuit layer;
a first line configured to be electrically connected to the transistor of the first pixel circuit layer;
a second line configured to be electrically connected to the transistor of the second pixel circuit layer; and
a connection line configured to electrically connect the first line and the second line and comprising nanostructures,
wherein the connection line comprises a first end portion, a second end portion opposite to the first end portion, and a body between the first end portion and the second end portion,
wherein the first line is on the first end portion of the connection line and directly contacts the first end portion, and
wherein the second line is on the second end portion of the connection line and directly contacts the second end portion.

9. The display panel of claim 8, wherein the nanostructures comprise first nanostructures,
wherein each of the first end portion and the second end portion of the connection line comprises the first nanostructures in a network structure,
wherein the first line directly contacts the first nanostructures of the first end portion and at least partially fills a cavity between the first nanostructures of the first end portion, and
wherein the second line directly contacts the first nanostructures of the second end portion and at least partially fills a cavity between the first nanostructures of the second end portion.

10. The display panel of claim 9, wherein the nanostructures comprise second nanostructures,
wherein the body of the connection line comprises the second nanostructures configured to be electrically connected to the first nanostructures, and an elastomer, and
wherein a portion of the second nanostructures overlap and contact a portion of the first nanostructures.

11. The display panel of claim 10, wherein each of the first nanostructures and the second nanostructures comprises at least one of a nanowire, a nanofiber, a nanotube, a nanorod, a nanobelt, and a nanoflake.

12. The display panel of claim 8, wherein the body of the connection line is on the first surface of the base layer,
wherein the first end portion of the connection line is on at least one of the insulating layers of the first pixel circuit layer, and
wherein the second end portion of the connection line is on at least one of the insulating layers of the second pixel circuit layer.

13. The display panel of claim 8, wherein each of the body, the first end portion, and the second end portion of the connection line is on the first surface of the base layer,
wherein the first line extends toward the first surface of the base layer so that a portion of the first line contacts the first end portion, and
wherein the second line extends toward the first surface of the base layer so that a portion of the second line contacts the second end portion.

14. An electronic device comprising:
a base layer comprising a first surface and a second surface opposite to the first surface;
a first pixel circuit layer on the first surface of the base layer and comprising a transistor and insulating layers;
a second pixel circuit layer on the first surface of the base layer, spaced apart from the first pixel circuit layer, and comprising a transistor and insulating layers;
a first light-emitting diode on the first pixel circuit layer and configured to be electrically connected to the transistor of the first pixel circuit layer;
a second light-emitting diode on the second pixel circuit layer and configured to be electrically connected to the transistor of the second pixel circuit layer;
a first line configured to be electrically connected to the transistor of the first pixel circuit layer;
a second line configured to be electrically connected to the transistor of the second pixel circuit layer; and
a connection line configured to electrically connect the first line and the second line and comprising nanostructures,
wherein the connection line comprises a first end portion, a second end portion opposite to the first end portion, and a body between the first end portion and the second end portion,
wherein the first line overlaps the first end portion of the connection line, and
wherein the second line overlaps the second end portion of the connection line.

15. The electronic device of claim 14, wherein the nanostructures comprise first and second nanostructures,
wherein each of the first end portion and the second end portion of the connection line comprises the first nanostructures, and
wherein the body of the connection line comprises the second nanostructures configured to be electrically connected to the first nanostructures, and an elastomer,
wherein each of the first nanostructures and the second nanostructures comprises at least one of a nanowire, a nanofiber, a nanotube, a nanorod, a nanobelt, and a nanoflake.

16. The electronic device of claim 14, wherein the body of the connection line is on the first surface of the base layer,
wherein the first end portion of the connection line is on at least one of the insulating layers of the first pixel circuit layer, and
wherein the second end portion of the connection line is on at least one of the insulating layers of the second pixel circuit layer.

17. The electronic device of claim 14, wherein each of the body, the first end portion, and the second end portion of the connection line is on the first surface of the base layer,
wherein the first line extends toward the first surface of the base layer so that a portion of the first line contacts the first end portion, and
wherein the second line extends toward the first surface of the base layer so that a portion of the second line contacts the second end portion.

18. The electronic device of claim 14, further comprising:
a first conductor on a first overlapping portion between the first line and the first end portion; and
a second conductor on a second overlapping portion between the second line and the second end portion.

19. The electronic device of claim 18, wherein each of the connection line, the first conductor, and the second conductor is in a concave portion that is recessed from the first surface of the base layer.

20. The electronic device of claim 18, wherein the first conductor contacts the first overlapping portion between the first line and the first end portion on an upper surface of at least one of the insulating layers of the first pixel circuit layer, and
wherein the second conductor contacts the second overlapping portion between the second line and the second end portion on an upper surface of at least one of the insulating layers of the second pixel circuit layer.
